(19) United States
(12) Patent Application Publication
(10) Pub. No.: US 2026/0206614 A1
(43) Pub. Date: Jul. 16, 2026

(54) ELECTRONIC DEVICE AND METHOD FOR MANUFACTURING ELECTRONIC DEVICE

(71) Applicant: ROHM CO., LTD., Kyoto-shi (JP)

(72) Inventors: Shingo YOSHIDA, Kyoto-shi (JP); Ryotaro KAKIZAKI, Kyoto-shi (JP)

(21) Appl. No.: 19/564,378

(22) Filed: Mar. 12, 2026

Related U.S. Application Data
(63) Continuation of application No. PCT/JP2024/031154, filed on Aug. 30, 2024.

(30) Foreign Application Priority Data
Sep. 19, 2023 (JP) 2023-151336

(51) Int. Cl. H10W 70/40; H10W 70/04; H10W 72/50; H10W 90/00; H10W 72/00

(52) U.S. Cl. CPC H10W 70/427; H10W 70/048; H10W 72/527; H10W 90/736; H10W 90/757; H10W 72/884

(57) ABSTRACT

An electronic device includes a first member with a first obverse surface, an electronic element on the first member, a connecting member connected to the electronic element, a second member with a second reverse surface, and a sealing resin covering the first member, the second member, the electronic element, and the connecting member. The second member includes a terminal portion and a connecting portion connected to the connecting member. The first obverse surface includes a first flat portion and a first projecting portion. The first projecting portion projects to the first side in the thickness direction relative to the first flat portion. The second reverse surface includes a second flat portion and a second projecting portion. The second projecting portion projects to the second side in the thickness direction relative to the second flat portion.

### TECHNICAL FIELD

The present disclosure relates to electronic devices and methods for manufacturing electronic devices.

### BACKGROUND ART

Various electronic devices incorporating electronic components have been proposed. For example, JP-A-2018-113359 discloses a semiconductor device as an example of a conventional electronic device. The semiconductor device of JP-A-2018-113359 comprises a semiconductor element, a first lead, an adhesive, and a resin package.

### BRIEF DESCRIPTION OF THE DRAWINGS

FIG. 1 is a perspective view showing an electronic device according to a first embodiment of the present disclosure.

FIG. 2 is a perspective view showing the electronic device according to the first embodiment.

FIG. 3 is a plan view showing the electronic device according to the first embodiment.

FIG. 4 is a cross-sectional view along line IV-IV in FIG. 3.

FIG. 5 is an enlarged cross-sectional view showing principal portions of the electronic device according to the first embodiment.

FIG. 6 is a cross-sectional view along line VI-VI in FIG. 3.

FIG. 7 is a cross-sectional view along line VII-VII in FIG. 3.

FIG. 8 is an enlarged cross-sectional view showing the principal portions of the electronic device according to the first embodiment.

FIG. 9 is a cross-sectional view along line IX-IX in FIG. 3.

FIG. 10 is a partial plan view showing an example of a manufacturing method for the electronic device according to the first embodiment.

FIG. 11 is a partially enlarged cross-sectional view along line XI-XI inf FIG. 10.

FIG. 12 is a partially enlarged cross-sectional view showing an example of a manufacturing method for the electronic device according to the first embodiment.

FIG. 13 is a partially plan view showing an example of a manufacturing method for the electronic device according to the first embodiment.

FIG. 14 is a partially enlarged cross-sectional view along line XIV-XIV in FIG. 13.

FIG. 15 is a partially enlarged cross-sectional view showing an example of a manufacturing method for the electronic device according to the first embodiment.

FIG. 16 is a partial plan view showing an example of a manufacturing method for the electronic device according to the first embodiment.

FIG. 17 is a perspective view showing a semiconductor device according to a second embodiment of the present disclosure.

FIG. 18 is a perspective view showing the semiconductor device according to the second embodiment.

FIG. 19 is a perspective view showing the semiconductor device according to the second embodiment.

FIG. 20 is a partial perspective view showing the principal portions of the semiconductor device according to the second embodiment.

FIG. 21 is a perspective view showing the principal portions of the semiconductor device according to the second embodiment.

FIG. 22 is a plan view showing the semiconductor device according to the second embodiment.

FIG. 23 is a bottom view showing the semiconductor device according to the second embodiment.

FIG. 24 is a front view showing the semiconductor device according to the second embodiment.

FIG. 25 is a side view showing the semiconductor device according to the second embodiment.

FIG. 26 is a plan view showing the principal portions of the semiconductor device according to the second embodiment.

FIG. 27 is a bottom view showing the principal portions of the semiconductor device according to the second embodiment.

FIG. 28 is a cross-sectional view along line XXVII-XXVII in FIG. 27.

FIG. 29 is an enlarged view showing a portion of FIG. 28.

FIG. 30 is a cross-sectional view along line XXX-XXX in FIG. 27.

FIG. 31 is an enlarged view showing a portion of FIG. 30.

FIG. 32 is a cross-sectional view along line XXXII-XXXII in FIG. 27.

FIG. 33 is an enlarged view showing a portion of FIG. 32.

FIG. 34 is a sectional view along line XXXIV-XXXIV in FIG. 27.

FIG. 35 is a sectional view showing a first variation of the semiconductor device according to the second embodiment.

FIG. 36 is an enlarged view showing a portion of FIG. 35.

FIG. 37 is a cross-sectional view showing the first variation of the semiconductor device according to the second embodiment.

FIG. 38 is an enlarged view showing a portion of FIG. 37.

FIG. 39 is a cross-sectional view showing the first variation of the semiconductor device according to the second embodiment.

FIG. 40 is an enlarged view showing a portion of FIG. 39.

FIG. 41 is a cross-sectional view showing the first variation of the semiconductor device according to the second embodiment.

FIG. 42 is a cross-sectional view showing the application of the first variation of the semiconductor device according to the second embodiment.

### DETAILED DESCRIPTION OF EMBODIMENTS

Preferred embodiments according to the present disclosure will be described below with reference to the accompanying drawings.

The same reference numerals are used for identical or similar components, and redundant descriptions may be omitted. The terms “first,” “second,” etc., in this disclosure are used merely as labels and do not necessarily imply any particular order of the objects.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

For convenience of explanation, reference is made to mutually orthogonal thickness direction z, first direction x, and second direction y. The thickness direction z may correspond to the thickness direction of the electronic device A100. In the following description, one side in the thickness direction z may be referred to as the upper side or first side z1. The opposite side in the thickness direction z may be referred to as the lower side or second side z2. Descriptions such as “top,” “bottom,” “upper,” “lower,” “top surface,” and “bottom surface” may indicate the relative positions of components, with respect to the thickness direction z and do not necessarily define terms related to the direction of gravity. “Plan view” may refer to the view of an object when observed in or along the thickness direction z.

### FIRST EMBODIMENT

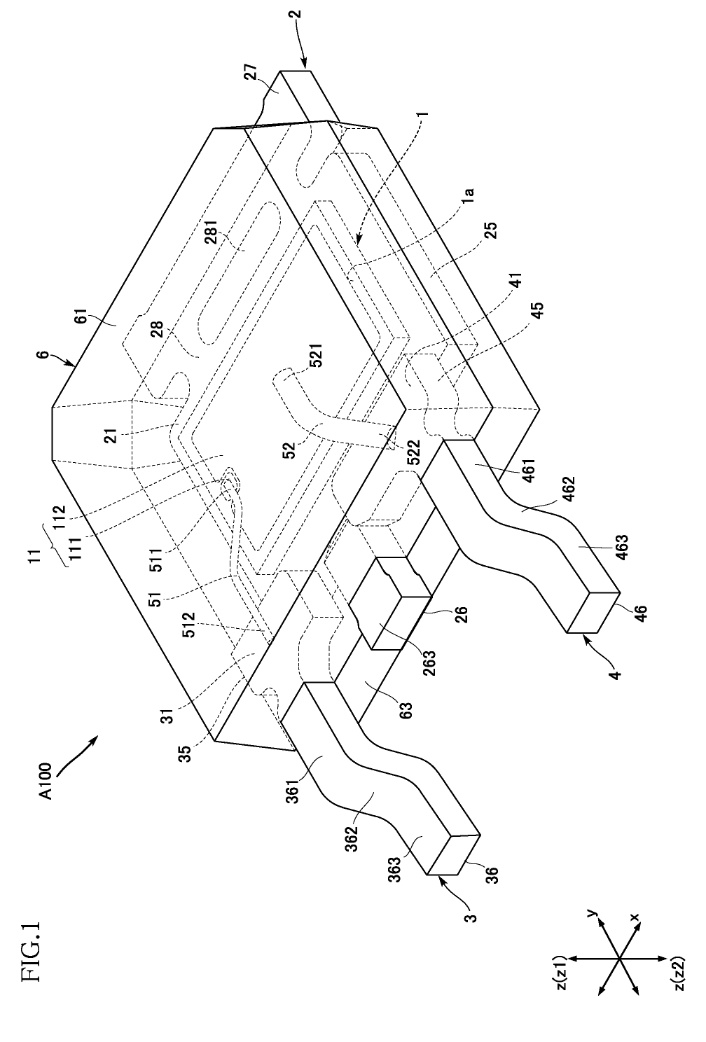

FIGS. 1 to 9 show an electronic device according to a first embodiment of the present disclosure. The electronic device A100 of this embodiment comprises an electronic element 1, a first member 2, two second members 3 and 4, two connecting members 51 and 52, and a sealing resin 6.

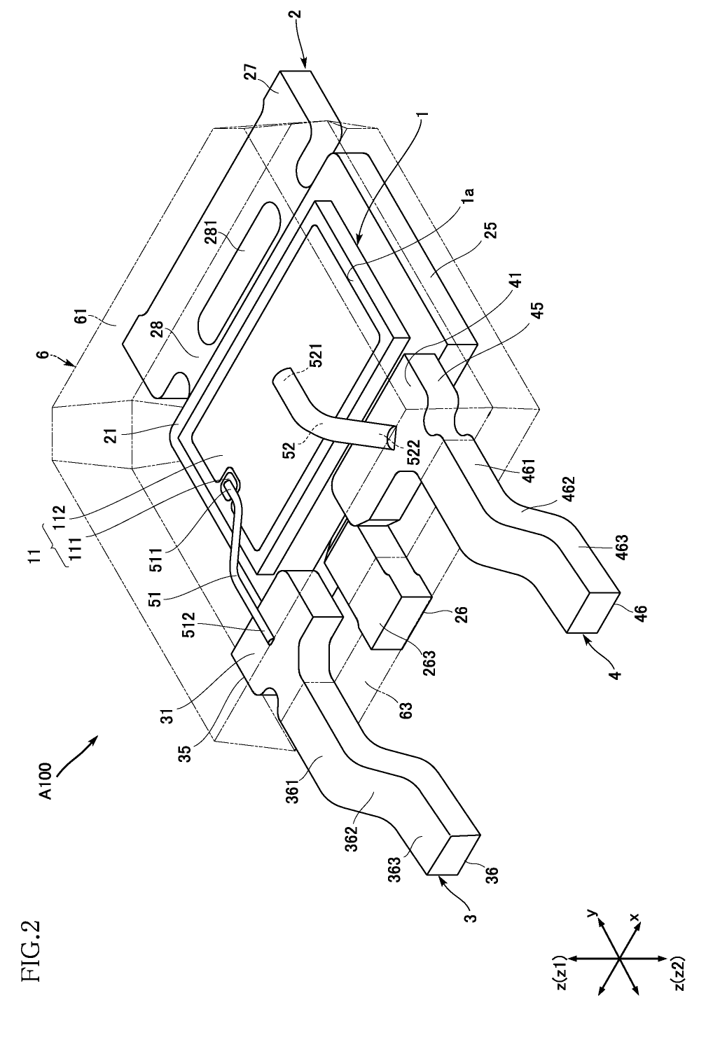

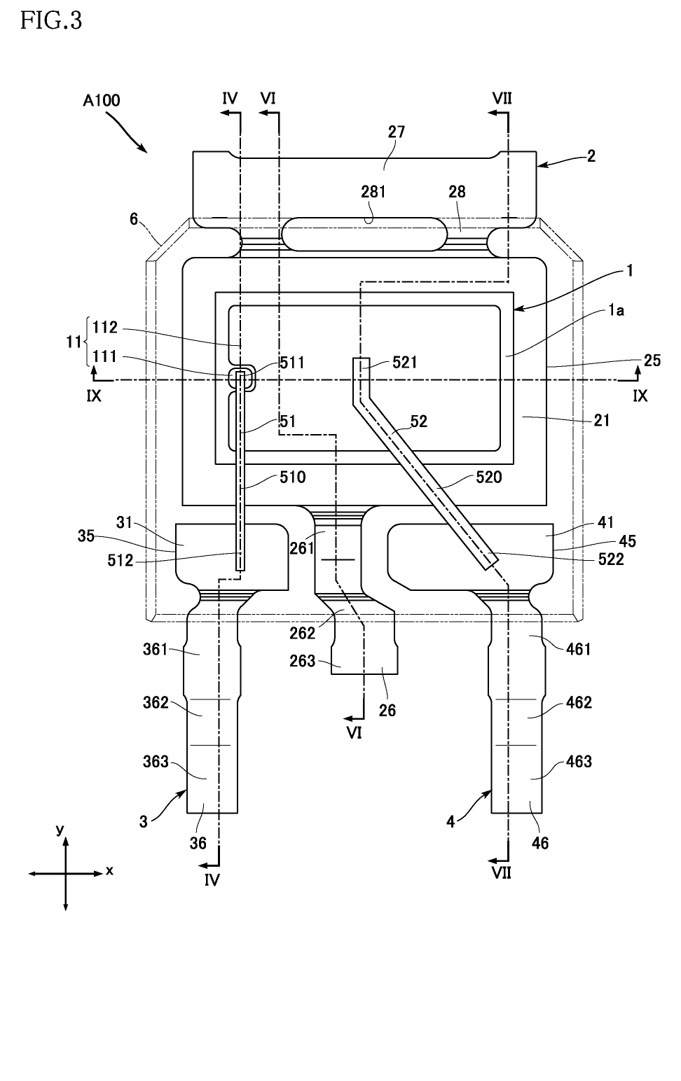

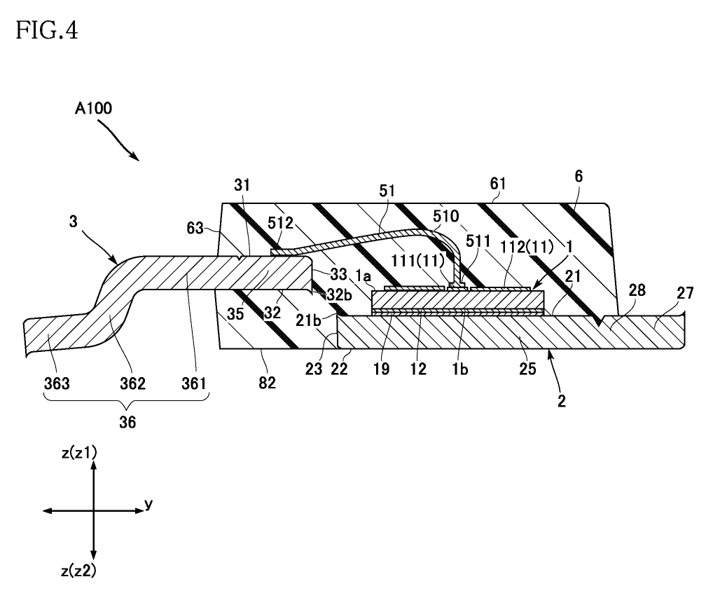

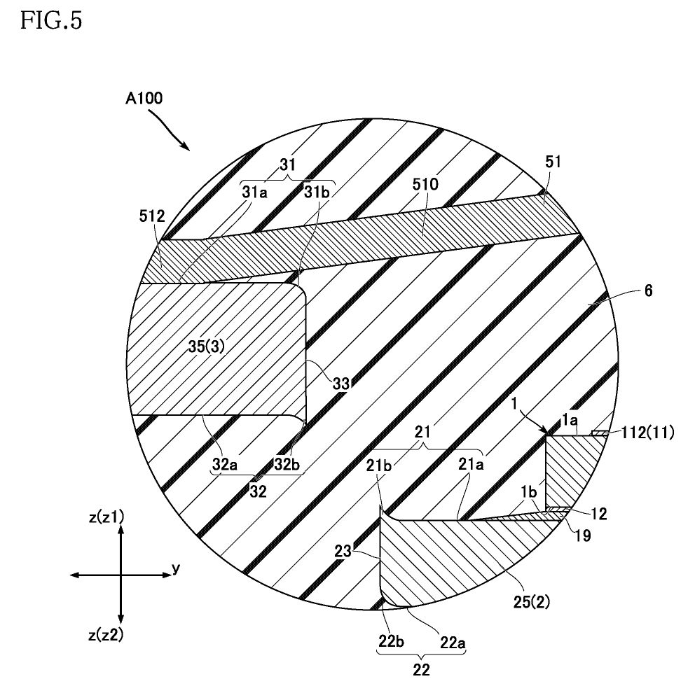

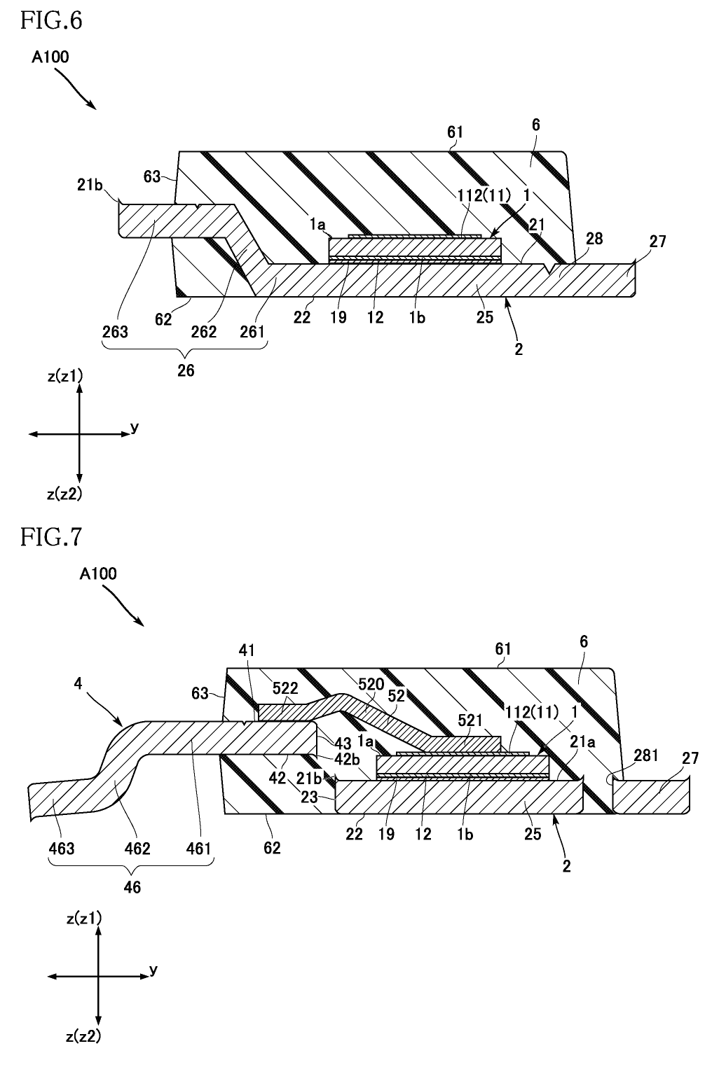

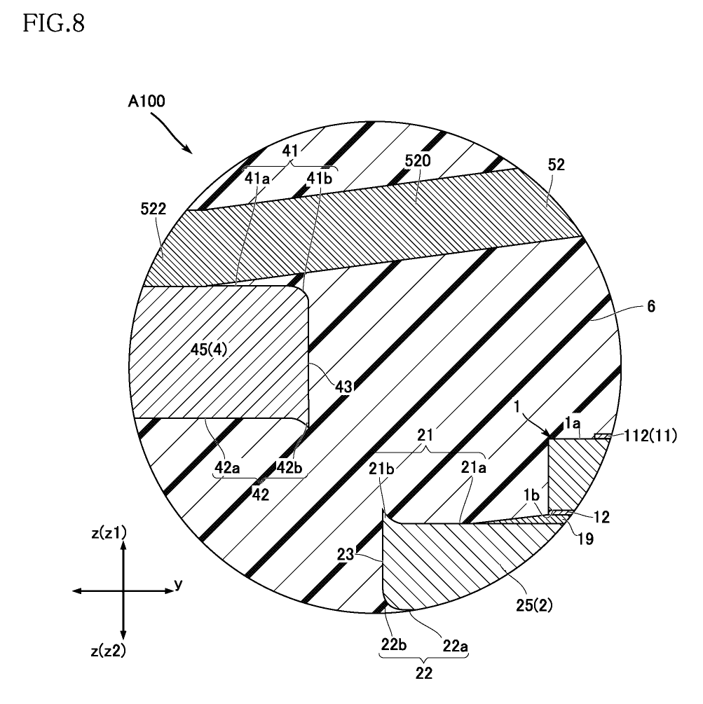

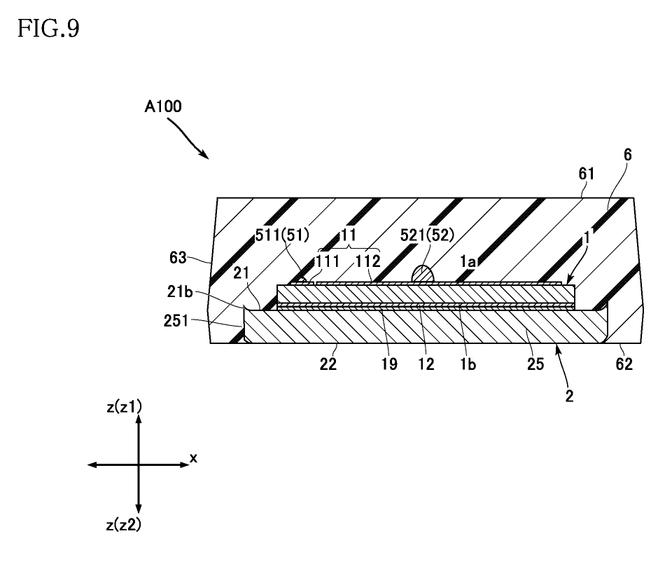

FIG. 1 and FIG. 2 are a perspective view showing the electronic device A100. FIG. 3 is a plan view showing the electronic device A100. FIG. 4 is a sectional view along line IV-IV in FIG. 3. FIG. 5 is an enlarged view showing principal portions of the electronic device A100. FIG. 6 is a cross-sectional view along line VI-VI in FIG. 3. FIG. 7 is a cross-sectional view along line VII-VII in FIG. 3. FIG. 8 is an enlarged cross-sectional view showing the principal portions of the electronic device according to the first embodiment of the present disclosure. FIG. 9 is a cross-sectional view along line IX-IX in FIG. 3. In this embodiment, a first side z1 in the thickness direction z may correspond to "one side", and a second side z2 may correspond to the "other (or opposite) side".

The electronic element 1 is an electronic component configured to serve as the functional core of the electronic device A100, and it may be made of a semiconductor material, for example. The semiconductor materials may include Si (silicon), SiC (silicon carbide), and GaAs (gallium arsenide), but are not limited to these. The electronic element 1 is, for example, a power semiconductor chip such as a MOSFET (Metal Oxide Semiconductor Field Effect Transistor). In the present embodiment, the electronic element 1 is a MOSFET. Alternatively, other transistors such as an IGBT (Insulated Gate Bipolar Transistor) or diodes such as a Schottky barrier diode and a fast recovery diode may be used instead.

The electronic element 1 of this embodiment has an element obverse surface 1a, an element reverse surface 1b, a plurality of obverse surface electrodes 11, and a drain electrode 12. The element obverse surface 1a faces the first side z1 in the thickness direction z (the upper side in FIGS. 1, 2, 4, 7, and 8). The element reverse surface 1b faces the second side z2 (the lower side in FIGS. 1, 2, 4, 7, and 8) in the thickness direction z, which is opposite to the element obverse surface 1a.

As shown in FIGS. 1 to 3, the plurality of obverse surface electrodes 11 are formed on the element obverse surface 1a. In this embodiment, the plurality of obverse surface electrodes 11 include a gate electrode 111 and a source electrode 112. The gate electrode 111 is the electrode to which a gate voltage is applied in using the electronic device A100 as a switching device. The source electrode 112 is used as an input/output terminal. In the illustrated example, the gate electrode 111 is smaller than the source electrode 112. The gate electrode 111 is positioned biased toward one side (the left side in FIG. 3) of the element obverse surface 1a in the first direction x. The drain electrode 12 is formed on the element reverse surface 1b and, like the source electrode 112, is used as an input/output terminal.

The first member 2 is a member on which the electronic element 1 is mounted. The first member 2 is made of a first metal. The first metal in this embodiment may be, for example, Cu (copper), but is not limited thereto; it may also be Ni (nickel), or an alloy of Cu (copper), an alloy of Ni, or 42 alloy. The first member 2 may be formed, for example, by punching a thin-walled Cu (copper) metal plate having a rectangular shape in plan view. The method for forming the first member 2 is not limited to this; it may be formed by cutting or bending with respect to a metal plate. As shown in FIGS. 1 to 3 and FIGS. 6 to 8, the first member 2 of this embodiment has a pad portion 25, an extending portion 26, a protruding portion 27, and a linking portion 28.

The first member 2 has a first obverse surface 21, a first reverse surface 22, and a first side surface 23. The first obverse surface 21 faces the first side z1 in the thickness direction z, and the first reverse surface 22 faces the second side z2 in the thickness direction z. In this embodiment, the first obverse surface 21 may correspond to the “first surface”. The upper edge or end of the first side surface 23 in the thickness direction z connects to the first obverse surface 21, and the lower edge or end of the first side surface 23 in the thickness direction z connects to the first reverse surface 22. The first obverse surface 21 has a first obverse surface flat portion 21a and a first obverse surface projecting portion 21b. In this embodiment, the first obverse surface flat portion 21a may correspond to the “first flat portion,” and the first obverse surface projecting portion 21b may correspond to the “first projecting portion.” The first obverse surface projecting portion 21b projects toward the first side z1 in the thickness direction z relative to or with respect to the first obverse surface flat portion 21a. The first obverse surface projecting portion 21b is in contact with the first side surface 23. The first reverse surface 22 has a first reverse surface flat portion 22a and a first reverse surface recessed portion 22b. The first reverse surface recessed portion 22b is recessed toward the first side z1 in the thickness direction z relative to the first reverse surface flat portion 22a. The first reverse surface recessed portion 22b is in contact with the first side surface 23. The present disclosure may also include a configuration where only one of the first obverse surface projecting portion 21b and the first reverse surface recessed portion 22b is provided.

The extending portion 26 extends from the pad portion 25 toward one side in the second direction y (the side where the connecting portions 35, 45, described later, are located with respect to the pad portion, as shown in FIGS. 1 to 3 and FIG. 6. The shape of the extending portion 26 is not particularly limited. In the illustrated example, the extending portion 26 has a root portion 261, a bent portion 262, and a front end portion 263.

The root portion 261 extends from the pad portion 25 toward one side in the second direction y and has a shape elongated along the second direction y. The bent portion 262 connects to the tip of the root portion 261 in the second direction y and has a bent shape toward the first side z1 in the thickness direction z as viewed in the first direction x. The front end portion 263 is connected to the bent portion 262 and extends from the bent portion 262 along the second direction y toward one side of the second direction y. In the illustrated example, a portion of the front end portion 263 protrudes from the sealing resin 6.

The protruding portion 27 is positioned opposite from the pad portion 25 toward the other side in the second direction y, as shown in FIGS. 1 to 3 and FIG. 7. The shape of the protruding portion 27 is not limited. In the illustrated example, the protruding portion 27 has a generally elongated rectangular shape extending along the first direction xa as viewed in the thickness direction z, and most of it is exposed from the sealing resin 6.

The linking portion 28 connects the pad portion 25 and the protruding portion 27 to each other. In the example shown in FIG. 3, the linking portion 28 is formed with a through hole 281. The through hole 281 penetrates the linking portion 28 in the thickness direction z.

The second member 3 is a member to which the connecting member 51 described later is joined. The second member 3 is made of a first metal. The second member 3 may be formed, for example, by punching a thin-walled metal plate of Cu having a rectangular shape in plan view. The method for forming the second member 3 is not limited to this; it may be formed by cutting, bending, or other processes. As shown in FIGS. 1 to 4, the second member 3 of this embodiment has a connecting portion 35 and a terminal portion 36.

The second member 3 has a second obverse surface 31, a second reverse surface 32, and a second side surface 33. The second obverse surface 31 faces the first side z1 in the thickness direction z, and the second reverse surface 32 faces the second side z2 in the thickness direction z. In this embodiment, the second reverse surface 32 may correspond to the “second surface”. The upper edge or end of the second side surface 33 in the thickness direction z connects to the second obverse surface 31, and the lower edge or end of the second side surface 33 in the thickness direction z connects to the second reverse surface 32. In the second member 3, the connecting member 51 described later is joined to the second obverse surface 31 of the connecting portion 35. The second obverse surface 31 has a second obverse surface flat portion 31a and a second obverse surface recessed portion 31b. The second obverse surface recessed portion 31b is recessed toward the second side z2 in the thickness direction z relative to the second obverse surface flat portion 31a. The second obverse surface recessed portion 31b is in contact with the second side surface 33. The second reverse surface 32 has a second reverse surface flat portion 32a and a second reverse surface projecting portion 32b. In this embodiment, the second reverse surface flat portion 32a may correspond to the “second flat portion,” and the second reverse surface projecting portion 32b may correspond to the “second projecting portion.” The second reverse surface projecting portion 32b projects toward the second side z2 in the thickness direction z relative to the second reverse surface flat portion 32a. The second reverse surface projecting portion 32b is in contact with the second side surface 33. This disclosure includes a configuration wherein only one of the second obverse surface recessed portion 31b and the second reverse surface projecting portion 32b is formed.

As shown in FIGS. 1 to 4, in this embodiment, the connecting portion 35 is positioned on one side in the second direction y relative to the pad portion 25 as viewed in the thickness direction z, while also being positioned on one side in the first direction x relative to the extending portion 26. In this embodiment, the connecting portion 35 is positioned on the first side z1 in the thickness direction z relative to the pad portion 25 and the extending portion 26. The position of the connecting portion is not limited to this; it may be positioned on the second side z₂ in the thickness direction z relative to the pad portion 25 and the extending portion 26, or it may be positioned substantially at the same location in the thickness direction z as the pad portion 25 and the extending portion 26.

The terminal portion 36 extends from the connecting portion 35 toward one side in the second direction y, as shown in FIGS. 1 to 4. The terminal portion 36 may be used in mounting the electronic device A100 onto a circuit board, for example. The shape of the terminal portion 36 is not particularly limited. In the illustrated example, the terminal portion 36 includes a root portion 361, a bent portion 362, and a front end portion 363.

The root portion 361 extends from the connecting portion 35 toward one side of the second direction y and has a shape elongated along the second direction y. A portion of the root portion 361 is exposed from the sealing resin 6. The bent portion 362 connects to the end of the root portion 361 in the second direction y and has a bent shape toward the second side z2 in the thickness direction z as viewed in the first direction x. The front end portion 363 connects to the bent portion 362 and extends from the bent portion 362 along the second direction y toward one side of the second direction y.

The second member 4 is a member to which the connecting member 52 described later is joined. The second member 4 is made of a first metal. The second member 4 is formed, for example, by punching a thin-walled metal plate of Cu having a rectangular shape in plan view. The method of forming the first member 2 is not limited to this, and it may be formed by cutting, or bending, for example. As shown in FIGS. 1 to 3 and FIG. 7, the second member 4 of this embodiment includes a connecting portion 45 and a terminal portion 46.

The second member 4 has a second obverse surface 41, a second reverse surface 42, and a second side surface 43. The second obverse surface 41 faces the first side z1 in the thickness direction z, and the second reverse surface 42 faces the second side z2 in the thickness direction z. The upper edge or end of the second side surface 43 in the thickness direction z connects to the second obverse surface 41, and the lower edge or end of the second side surface 43 in the thickness direction z connects to the second reverse surface 42. The connecting member 52 described later is joined to the second obverse surface 41 of the connecting portion 45 of the second member 4. The second obverse surface 41 includes a second obverse surface flat portion 41a and a second obverse surface recessed portion 41b. The second obverse surface recessed portion 41b is recessed toward the second side z2 in the thickness direction z relative to the second obverse surface flat portion 41a. The second obverse surface recessed portion 41b is in contact with the second side surface 43. The second reverse surface 42 includes a second reverse surface flat portion 42a and a second reverse surface projecting portion 42b. The second reverse surface projecting portion 42b projects toward the second side z₂ in the thickness direction z relative to the second reverse surface flat portion 42a. The second reverse surface projecting portion 42b is in contact with the second side surface 43. The present disclosure also includes a configuration where only one of the second obverse surface recessed portion 41b or the second reverse surface projecting portion 42b is formed.

As shown in FIGS. 1 to 3 and FIG. 8, in this embodiment, the connecting portion 45 is positioned on one side in the second direction y relative to the pad portion 25 as viewed in the thickness direction z, and is positioned on the other side in the first direction x relative to the extending portion 26. Further, in this embodiment, the connecting portion 45 is positioned on the first side z1 in the thickness direction z relative to the pad portion 25 and the extending portion 26. The position of the connecting portion is not limited to this; it may be positioned on the second side z2 in the thickness direction z relative to the pad portion 25 and the extending portion 26, or it may be positioned generally at the same location in the thickness direction z as the pad portion 25 and the extending portion 26.

The terminal portion 46 extends from the connecting portion 45 toward one side in the second direction y, as shown in FIGS. 1 to 3 and FIG. 7. The terminal portion 46 is used, for example, in mounting the electronic device A100 onto a circuit board, for example. The shape of the terminal portion 46 is not limited; in the illustrated example, the terminal portion 46 includes a root portion 461, a bent portion 462, and a front end portion 463.

The root portion 461 extends from the connecting portion 45 toward one side of the second direction y and has a shape elongated along the second direction y. A portion of the root portion 461 is exposed from the sealing resin 6. The bent portion 462 connects to the end of the root portion 461 in the second direction y and has a bent shape toward the second side z2 in the thickness direction z as viewed in the first direction x. The front end portion 463 connects to the bent portion 462 and extends along the second direction y from the bent portion 462 toward one side in the second direction y.

The connecting member 51 electrically connects the gate electrode 111 of the electronic element 1 and the second member 3 to each other. The specific configuration of the connecting member 51 is not limited; for example, it may be a wire or ribbon which is made of a metal. The metals constituting the connecting member 51 may include, for example, Al (aluminum), Au (gold), Cu (copper), for example, while also including an alloy containing one of these metals. The Al alloy may contain Fe (iron), or Si (silicon), or Ni (nickel) added to Al. In this embodiment, the connecting member 51 is a wire made of gold.

As shown in FIGS. 4 and 5, the connecting member 51 includes a bonding portion 511, a bonding portion 512, and a loop portion 510. The bonding portion 511 is connected to the gate electrode 111 of the electronic element 1A. The bonding portion 512 is connected to the connecting portion 35. In this embodiment, the gate electrode 111 to which the bonding portion 511 is connected is located on the first side z1 in the thickness direction z relative to the second obverse surface 31 of the connecting portion 35 to which the bonding portion 512 is connected. The loop portion 510 extends between the bonding portion 511 and the bonding portion 512 and has a shape bulging toward the z1 side in the thickness direction z.

The connecting member 52 electrically connects the source electrode 112 of the electronic element 1 and the second member 4 to each other. The specific configuration of the connecting member 52 is not limited, and the connecting member 52 may be a wire and a ribbon made of a metal. The metals constituting the connecting member 52 may include Al (aluminum), Au (gold), Cu (copper), and an alloy containing one of these metals. The Al alloy may contain Fe (iron), or Si (silicon), or Ni (nickel) added to Al. In this embodiment, the connecting member 52 is a wire made of aluminum or an Al alloy. In this case, the diameter of the connecting member 52 may be greater than the diameter of the connecting member 51.

As shown in FIGS. 7 and 8, the connecting member 52 includes a bonding portion 521, a bonding portion 522, and a loop portion 520. The bonding portion 521 is connected to the source electrode 112 of the electronic element 1A. The bonding portion 522 is connected to the connecting portion 45. In this embodiment, the source electrode 112 to which the bonding portion 521 is connected is positioned on the first side z1 in the thickness direction z relative to the second obverse surface 41 of the connecting portion 45 to which the bonding portion 522 is connected. The loop portion 520 extends between the bonding portion 521 and the bonding portion 522 and has a shape bulging toward the z1 side in the thickness direction z.

The sealing resin 6 covers the electronic element 1, a portion of the first member 2, a portion of the second member 3, a portion of the second member 4, the connecting member 51, and the connecting member 52. The sealing resin 6 may be made of a thermosetting synthetic resin having electrical insulating properties. In this embodiment, the sealing resin 6 is made of a black epoxy resin and may optionally contain certain fillers. As shown in FIGS. 1 to 4, FIG. 7 and FIG. 8, the sealing resin 6 has a resin obverse surface 61, a resin reverse surface 62, and a resin side surface 63, which may be a continuous wall surrounding the electronic element 1/the pad portion 25, as viewed in the thickness direction Z.

The resin obverse surface 61 and the resin reverse surface 62 face away from each other in the thickness direction z and are spaced apart from each other. The resin obverse surface 61 faces in the same direction as the element obverse surface 1a. The resin reverse surface 62 faces in the same direction as the element reverse surface 1b. The resin side surface 63 is in contact with the resin obverse surface 61 and the resin reverse surface 62.

In this embodiment, the first reverse surface 22 is exposed from the resin reverse surface 62. The extending portion 26, the protruding portion 27, the terminal portion 36, and the terminal portion 46 each protrude out from the resin side surface 63.

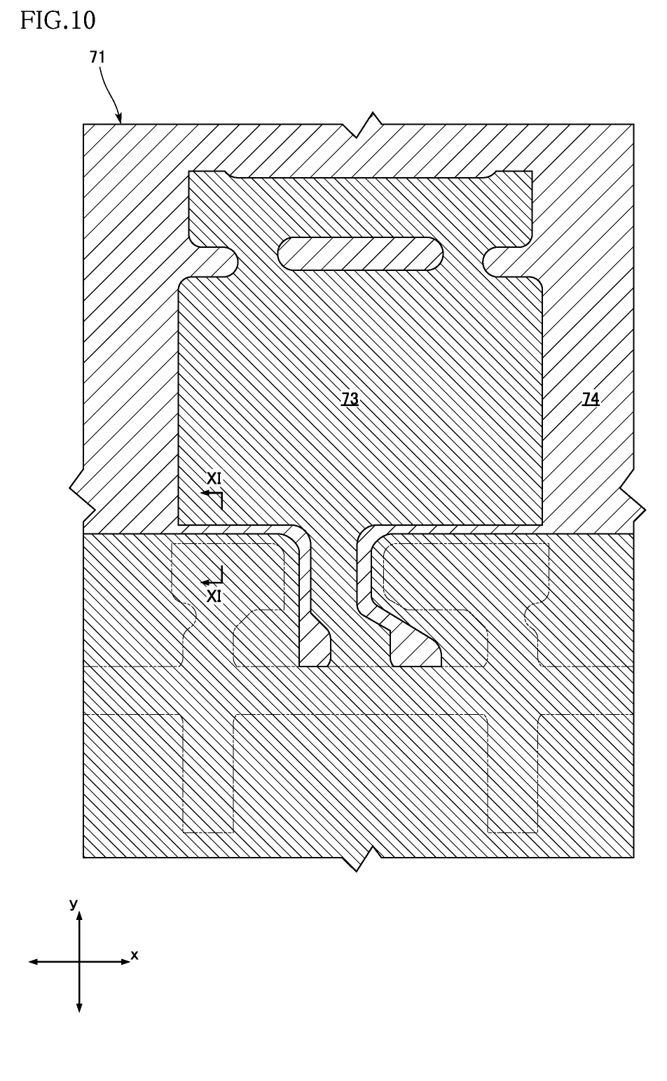

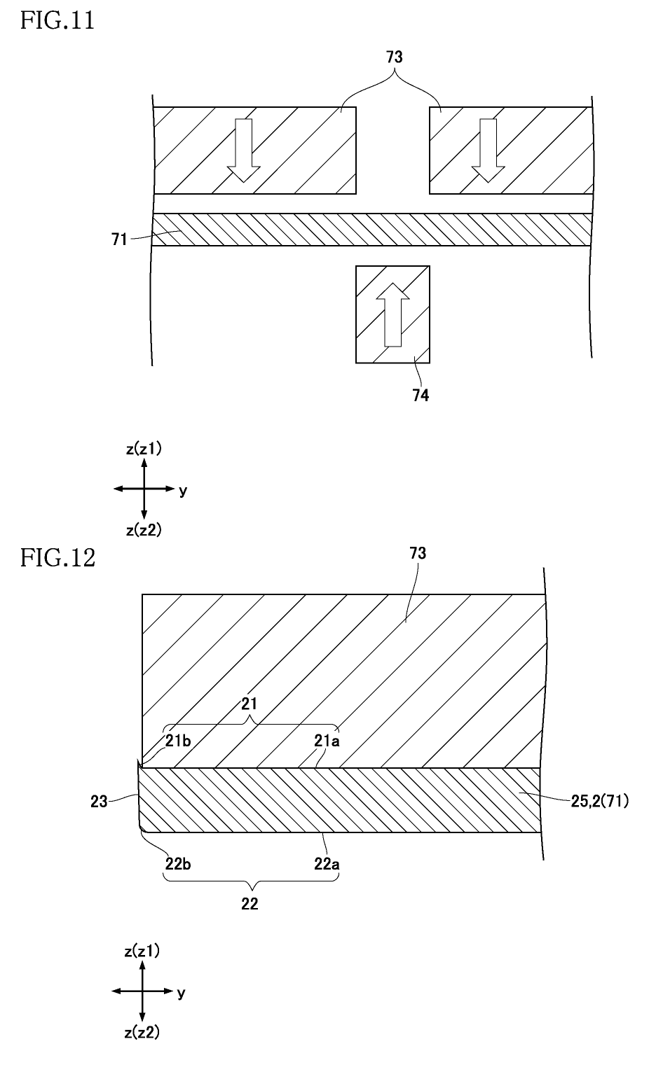

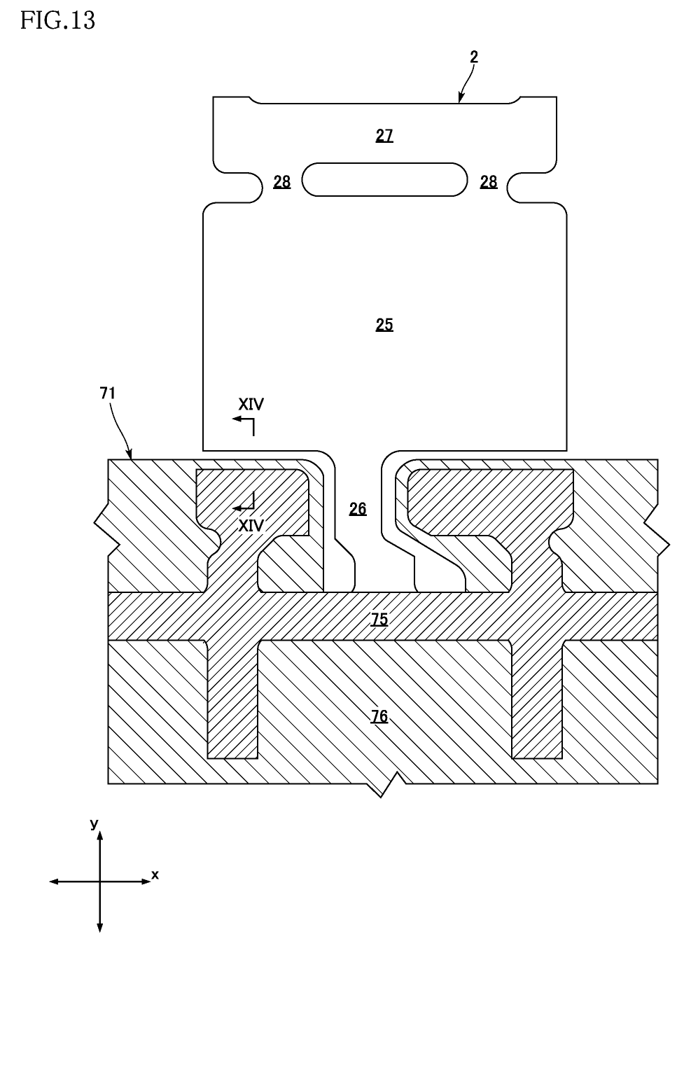

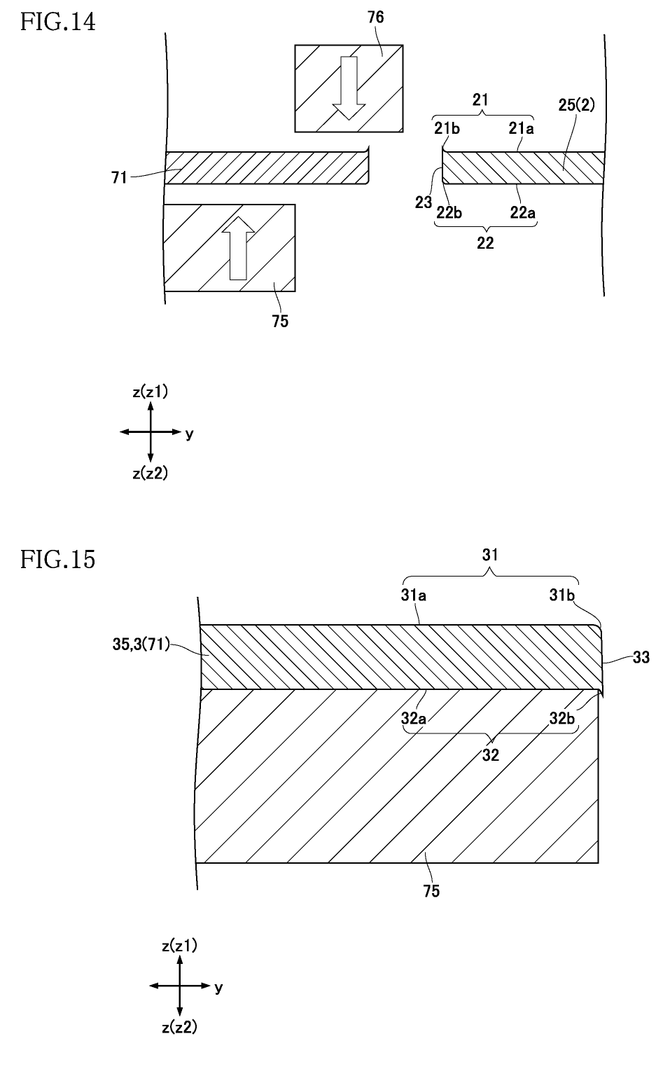

Next, an example of a manufacturing method for the electronic device A100 will be described with reference to FIGS. 10 to 16. FIG. 10 is a partial plan view showing a manufacturing method for the electronic device A100. FIG. 11 is a partial enlarged cross-sectional view along line XI-XI in FIG. 10. FIG. 12 is a partial enlarged cross-sectional view showing a manufacturing method for the electronic device A100. FIG. 13 is a partial plan view showing a manufacturing method for the electronic device A100. FIG. 14 is a partially enlarged cross-sectional view along line XIV-XIV in FIG. 13. FIG. 15 is a partially enlarged cross-sectional view showing a manufacturing method for the electronic device A100. FIG. 16 is a partial plan view showing a manufacturing method for electronic device A100.

As shown in FIGS. 10 and 11, a first die 73 is positioned on the first side z1 in the thickness direction z relative to a metal plate material 71, while a second die 74 is positioned on the second side z2 in the thickness direction z. Then, the first die 73 and the second die 74 are caused to move past each other in the thickness direction z to make cuts in the metal plate material 71. The portion of the metal plate material 71 that is in contact with the first die 73 becomes the first member 2 and remains in the metal plate material 71.

By passing the first die 73 and the second die 74 to each other in the thickness direction z, a cut face(s) is in the plate material by the shearing force. Thus, as shown in FIG. 12, the resulting first obverse surface 21 of the first member 2 includes a first obverse surface flat portion 21a and a first obverse surface projecting portion 21b, while the resulting first reverse surface 22 includes a first reverse surface flat portion 22a and a first reverse surface recessed portion 22b.

Next, as shown in FIGS. 13 and 14, a third die 75 is positioned on the second side z2 in the thickness direction z relative to the metal plate material 71, and a fourth die 76 is positioned on the first side z1 in the thickness direction z. Then, the third die 75 and the fourth die are caused to move past each other in the thickness direction z to make cuts in the the metal plate material 71. The portion of the metal plate material 71 that is in contact with the third die 75 becomes the second members 3 and 4.

By passing the third die 75 and the fourth die 76 to each other in the thickness direction z, a cut face(s) is in the plate material by the shearing force. Thus, as shown in FIG. 15, the resulting second obverse surface 31 of the second member 3 includes a second obverse surface flat portion 31a and a second obverse surface projecting portion 31b, while the resulting second reverse surface 32 includes a second reverse surface flat portion 32a and a second reverse surface recessed portion 32b.

Likewise, though not shown, shearing cut faces are formed in the second member 4 by causing the third die 75 and the fourth die 76 to move past each other in the thickness direction z. Thus, the second obverse surface 41 of the second member 4 includes a second obverse surface flat portion 41a and a second obverse surface recessed portion 41b, while the second reverse surface 42 includes a second reverse surface flat portion 42a and a second reverse surface projecting portion 42b.

FIG. 16 shows the metal plate material 71 after the first die 73 and the second die 74 are moved past each other in the thickness direction, and also the third die 75 and the fourth die 76 are moved past each other in the thickness direction. The frame portion 711 is a portion to which the first member 2 and the second members 3, 4 are connected.

In the manufacturing method above, the second members 3 and 4 are formed after the forming of the first member 2. Alternatively, the first member 2 may be formed after the forming of the second members 3, 4.

After the first member 2 and the second members 3, 4 are formed, the electronic element 1 is mounted on the first member 2.

Then, the electronic element 1 and the connecting portion 35 are connected to each other by the connecting member 51.

Then, the electronic element 1 and the connecting portion 45 are connected to each other by the connecting member 52.

Then, a sealing resin 6 is formed in a manner covering a part of the first member 2, the electronic element 1, the connecting portions 35, 45, and the connecting members 51, 52.

The advantages of the electronic device A100 are as follows.

According to the present embodiment, it is possible to provide the electronic device A100 with a more suitable package structure.

In this embodiment, as shown in FIGS. 4 and 5, the gate electrode 111 connected to the bonding portion 511 is positioned on the second side z2 in the thickness direction z relative to the second obverse surface 31 of the connecting portion 35 connected to the bonding portion 512. In this arrangement, the loop portion 510 of the connecting member 51 may interfere with the connecting portion 35. In the electronic device A100, the first member 2 has the first obverse surface projecting portion 21b, and the second member 3 has the second reverse surface projecting portion 32b. During the forming process of the second member 3, the die punching process for the second member 3 is performed in the opposite direction to the die punching process for the first member 2, so that the second reverse surface projecting portion 32b of the second member 3 will protrude toward the second side z2 in the thickness direction z, as shown in FIG. 5. In other words, the punching process reduces the formation of a protrusion on the second obverse surface 31. Consequently, it is possible to prevent connection failures such as breaking or interference of the connecting member 51 when bonding the connecting member 51 to the second obverse surface 31.

Further, In this embodiment, the source electrode 112 connected to the bonding portion 521 is positioned on the second side z2 in the thickness direction z relative to the second obverse surface 41 of the connecting portion 45 connected to the bonding portion 522. In this arrangement, the loop portion 520 of the connecting member 52 may interfere with the connecting portion 45. In the electronic device A100, the first member 2 has the first obverse surface projecting portion 21b, and the second member 4 has the second reverse surface projecting portion 42b. During the forming process of the second member 4, the die punching process for the second member 4 is performed in the opposite direction to the die punching process for the first member 2, so that the second reverse surface projecting portion 42b of the second member 4 will protrude toward the second side z2 in the thickness direction z, as shown in FIG. 8. In other words, the punching process reduces the formation of a protrusion on the second obverse surface 41. Consequently, it is possible to prevent connection failures such as breaking or interference of the connecting member 52 when bonding the connecting member 52 to the second obverse surface 41.

In the electronic device A100, the first obverse surface projecting portion 21b is provided on the first obverse surface 21 of the first member 2, and the first reverse surface recessed portion 22b is provided on the first reverse surface 22. The first reverse surface 22 may not be covered by the sealing resin 6. Since the first reverse surface has no protrusions, in mounting the electronic device A100, the adhesion of the first reverse surface 22 to another object may increase, thereby reducing connection failures during the mounting.

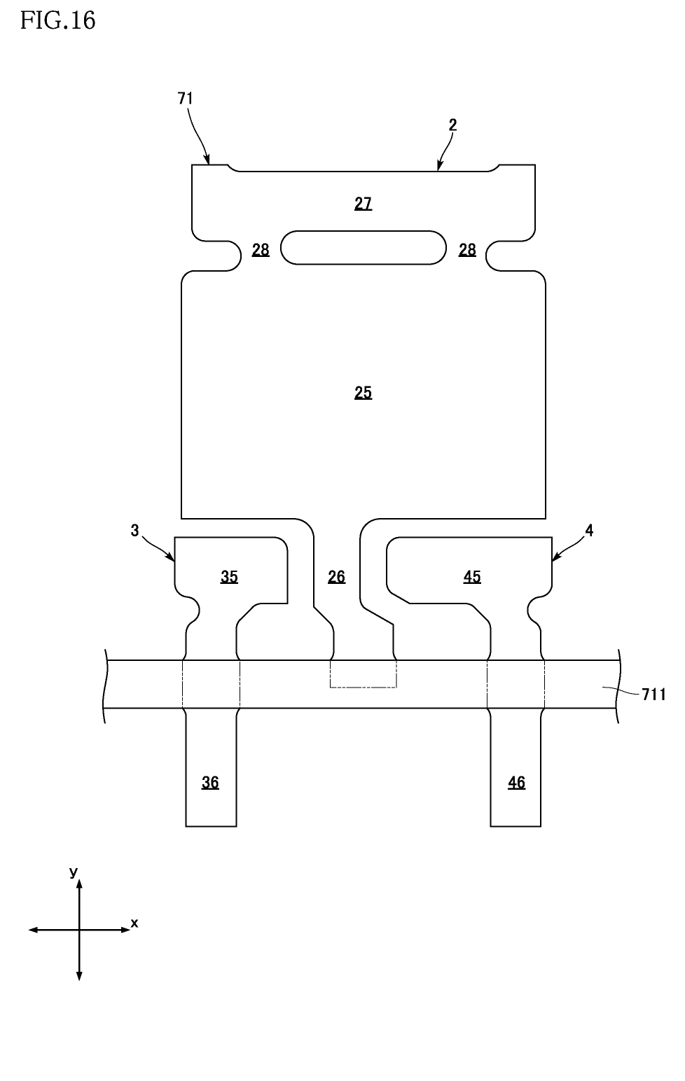

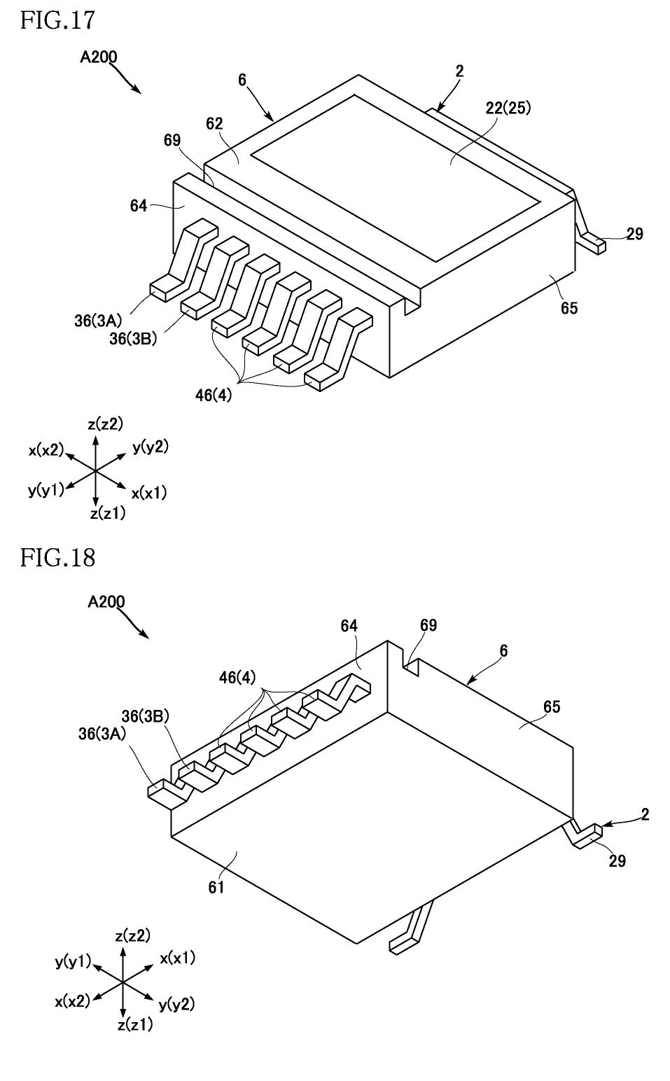

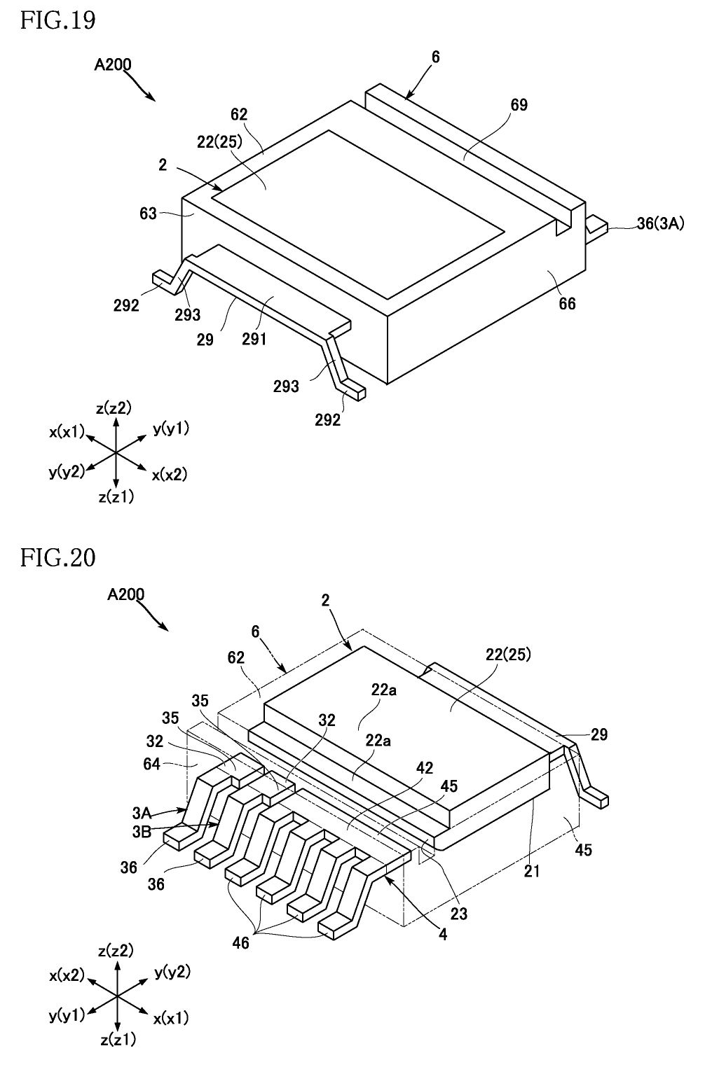

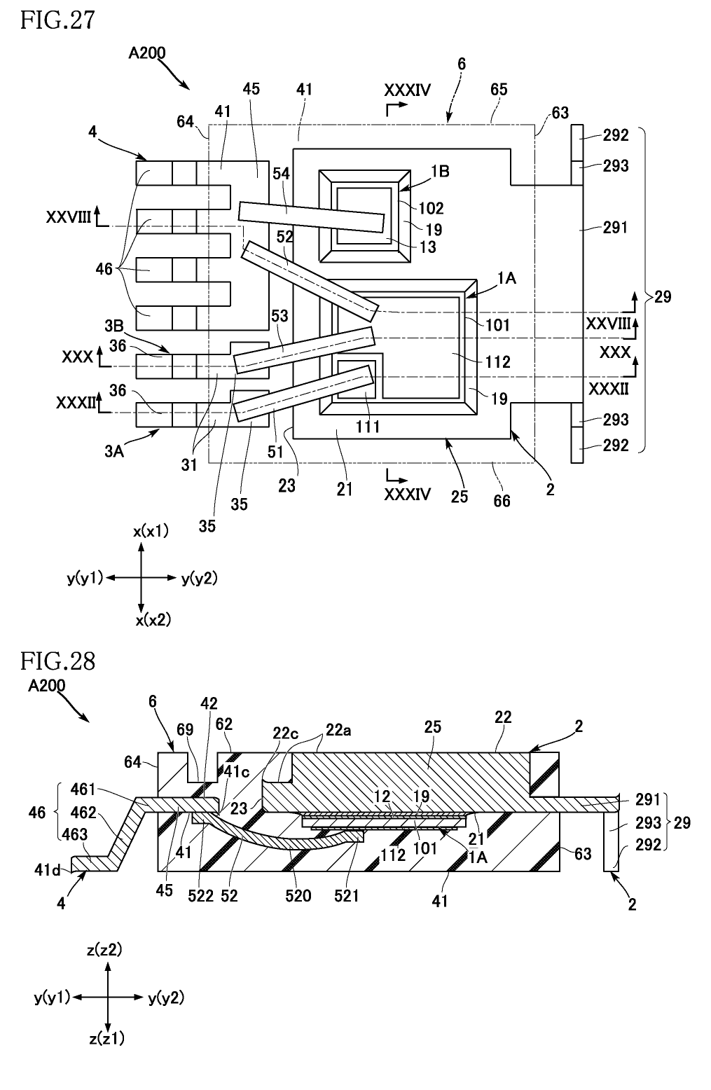

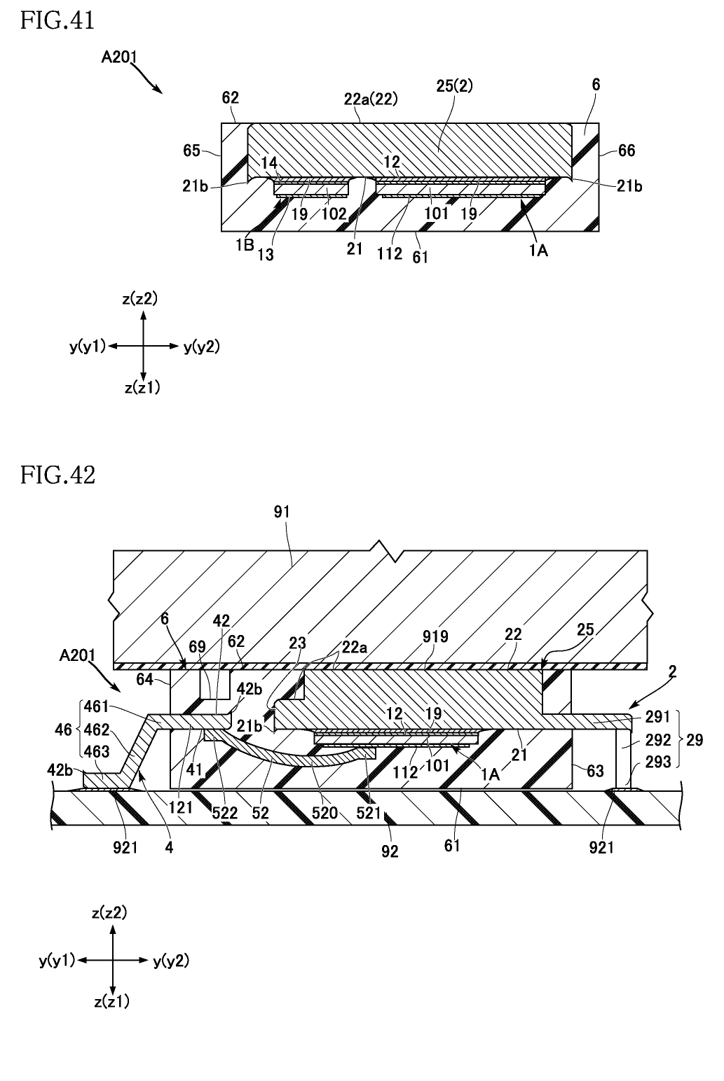

FIGS. 17 to 41 illustrate other embodiments and variations of the present disclosure. In these figures, elements identical or similar to those in the above embodiment are assigned the same reference numerals as in the above embodiment. The components in the respective embodiments and variations of the present disclosure can be appropriately combined or interchanged with one another as long as no technical contradiction arises.

### SECOND EMBODIMENT

FIGS. 17 to 34 illustrate a semiconductor device according to a second embodiment of the present disclosure. The electronic device A200 of this embodiment comprises a first member 2, a plurality of second members 4 and 3A-3B, an electronic element 1A, an electronic element 1B, connecting members 51, 52, 53 and 54, and a sealing resin 6. The electronic device A200 has a rectangular shape as viewed in the thickness direction.

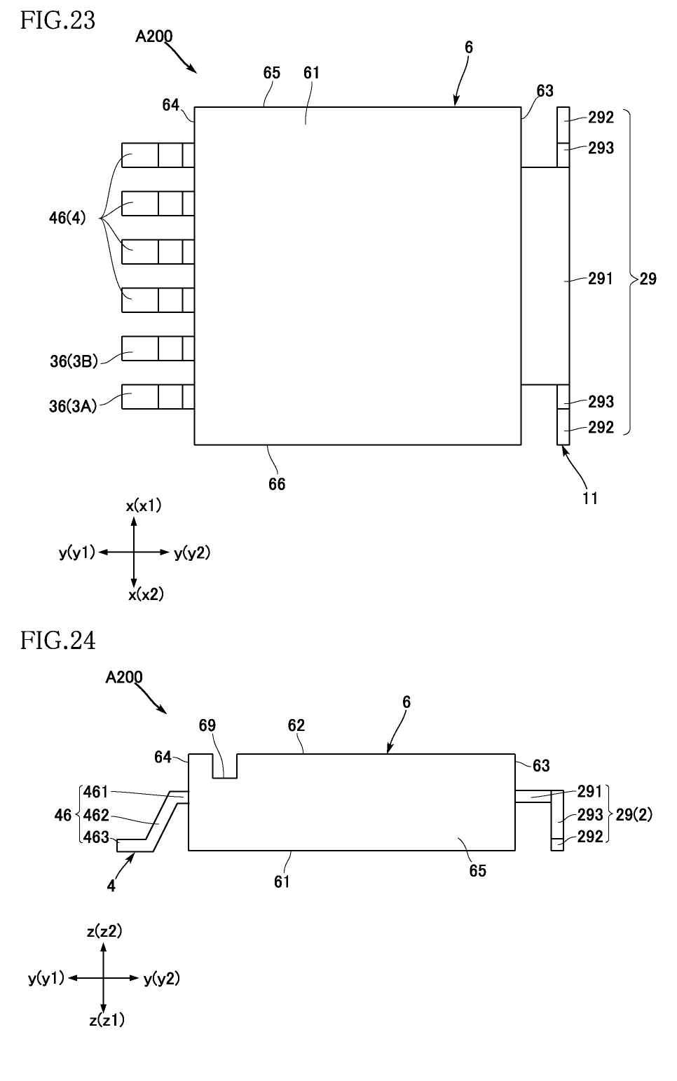

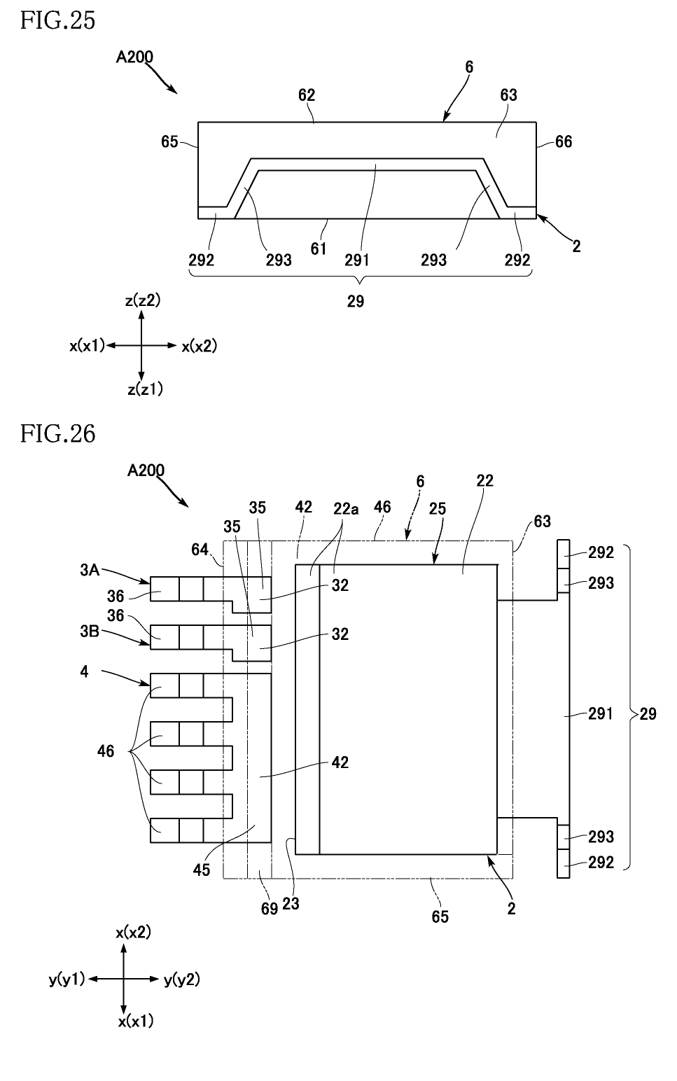

For convenience of explanation, the thickness direction of the electronic device A200 is referred to as the thickness direction z. The direction along one edge of the electronic device A200 that is orthogonal to the thickness direction z is referred to as the second direction y (the left-right direction in FIGS. 22 and 23). The direction perpendicular to both the thickness direction z and the second direction y (the vertical direction in FIGS. 22 and 23) is referred to as the first direction x. One side in the thickness direction z (the lower side in FIGS. 24 to 25) is referred to as the first side z1, and the opposite side (the upper side in FIGS. 24 to 25) is referred to as the second side z2. One side in the second direction y (the left side in FIGS. 22 and 23) is referred to as the first side y1, and the opposite side (the right side in FIGS. 22 and 23) is referred to as the second side y2. One side of the first direction x (lower side in FIG. 22) is referred to as the first side x1, and the opposite side (upper side in FIG. 22) is referred to as the second side x2. The shape and dimensions of the electronic device A200 are not limited to the illustrated example.

The first member 2, the second member 4, the second member 3A, and the second member 3B are components that form conductive paths to the electronic element 1A and the electronic element 1B. The material of the first member 2, the second member 4, the second member 3A, and the second member 3B is not limited and may include, for example, copper (Cu) or a copper alloy. The first member 2, the second member 4, the second member 3A, and the second member 3B may be plated with silver (Ag), nickel (Ni), tin (Sn), etc., at their appropriate locations.

As shown in FIGS. 17 to 34, the first member 2 has a first obverse surface 21 and a first reverse surface 22. The first obverse surface 21 faces the first side z1 in the thickness direction z. The first reverse surface 22 faces the second side z2 in the thickness direction z. Further, the first member 2 includes a pad portion 25 and a terminal portion 29. The electronic element 1A is mounted on the first obverse surface 21 of the pad portion 25.

The pad portion 25 of this embodiment includes a first side surface 23. The first side surface 23 faces a first side y1 in the second direction y and is positioned between the first obverse surface 21 and the first reverse surface 22 in the thickness direction z.

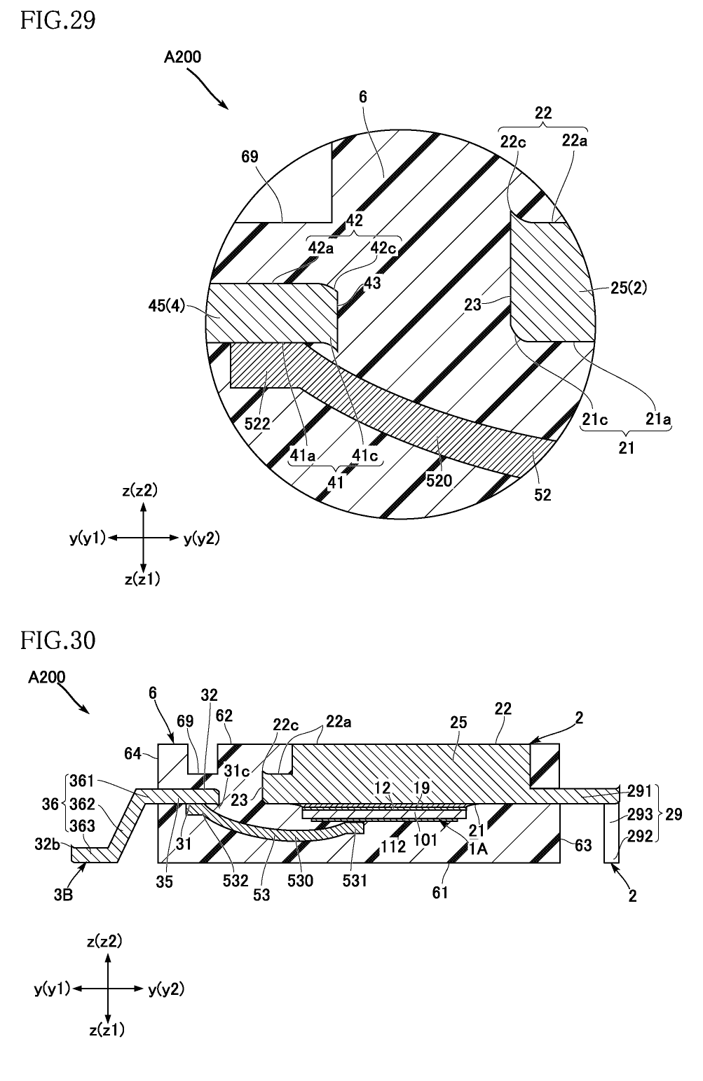

As shown in FIGS. 28 to 34, the first reverse surface 22 includes a first reverse surface flat portion 22a and a first reverse surface projecting portion 22c. In this embodiment, the first reverse surface 22 may correspond to the “first surface,” the first reverse surface flat portion 22a may correspond to the “first flat portion,” and the first reverse surface projecting portion 22c may correspond to the “first projecting portion.” In this embodiment, the second side z2 in the thickness direction z may correspond to “one side,” and the first side z1 may correspond to “the other side.” The first reverse surface flat portion 22a faces the second side z2 in the thickness direction z. In the illustrated example, the first reverse surface flat portion 22a is divided into multiple flat regions. The first reverse surface projecting portion 22c projects toward the second side z2 in the thickness direction z relative to the first reverse surface flat portion 22a. More precisely, the first reverse surface projecting portion 22c projects toward the second side z2 in the thickness direction z, with respect to the region of the first reverse surface flat portion 22a that is adjacent to the first reverse surface projecting portion 22c. In the illustrated example, as viewed in the thickness direction z, the first reverse surface projecting portion 22c is provided at an outer edge of the first reverse surface 22. The first reverse surface projecting portion 22c is in contact with the first side surface 23. The shape of the first reverse surface projecting portion 22c is not limited. In the example shown in FIGS. 29, 31, and 33, the first reverse surface projecting portion 22c is shaped to have a first surface extending up from the first side surface 23 toward the second side z2 in the thickness direction z, and a second concave curved surface that connects to the top of the first surface on the second side z2 in the thickness direction z and connects to the first reverse surface flat portion 22a.

The first obverse surface 21 includes a first obverse surface flat portion 21a and a first obverse surface recessed portion 21c. The first obverse surface flat portion 21a is a flat region facing the first side z1 in the thickness direction z. The first obverse surface recessed portion 21c is a portion sunk toward the second side z2 in the thickness direction z relative to the first obverse surface flat portion 21a. The first obverse surface recessed portion 21c may any portion located on the second side z2 in the thickness direction z relative to the region of the first obverse surface flat portion 21a that is adjacent to the first obverse surface recessed portion 21c. In the illustrated example, as viewed in the thickness direction z, the first obverse surface recessed portion 21c is provided at an outer edge of the first obverse surface 21. Further, the first obverse surface recessed portion 21c is in contact with the first side surface 23. The shape of the first obverse surface recessed portion 21c is not limited. In the example shown in FIGS. 29, 31, and 33, the first obverse surface recessed portion 21c is a convex curved surface connected to the first side surface 23 and to the first obverse surface flat portion 21a.

The shape of the pad portion 25 is not limited. In the illustrated example, the pad portion 25 is rectangular as viewed in the thickness direction z.

The terminal portion 29 includes a first part 291, two second parts 292, and two third parts 293.

The first part 291 is connected to the pad portion 25 and extends from the pad portion 25 to the second side y2 in the second direction y. In the illustrated example, the first part 291 is parallel to the x-y plane. In this embodiment, the pad portion 25 has a larger size in the thickness direction z than the first part 291. The terminal portion 29 of this embodiment includes only one first part 291. The shape of the first part 291 is not limited, and in the illustrated example, it is rectangular as viewed in the thickness direction z. The first part 291 is spaced apart from the first reverse surface 22 in the thickness direction z and, in the illustrated example, held in contact with the first obverse surface 21. One of the surfaces of the first part 291 is flush with the first obverse surface 21.

The two second parts 292 are positioned on the first side z1 in the thickness direction z relative to the first part 291. The two second parts 292 are used when surface-mounting the electronic device A200 onto a circuit board or the like.

The two third parts 293 are each interposed between the first part 291 and one of the two second parts 292. As a whole, each third part 293 extends from the first part 291 toward the first side z1 in the thickness direction z. In the illustrated example, each third part 293 is inclined relative to the thickness direction z as proceeding outward from the first part 291 in the first direction x. The shape of the third parts 293 is not limited; in the illustrated example, it is rectangular as viewed in the thickness direction z.

In this embodiment, the two second parts 292 extend outward from the two third parts 293 in the first direction x, respectively. Further, the two second parts 292 are parallel to the first direction x. The two second parts 292 do not protrude to the second side y2 in the second direction y relative to the two third parts 293. In the illustrated example, the two second parts 292 and the two third parts 293 have the same position in the second direction y.

The second member 4 is spaced apart from the first member 2 and located on the first side y1 of the second direction y relative to the pad portion 25. The second member 4 includes a second obverse surface 41 and a second reverse surface 42. Further, the second member 4 includes a connecting portion 45 and a plurality of terminal portions 46.

The second obverse surface 41 faces the first side z1 in the thickness direction z. The second reverse surface 42 faces the second side z2 in the thickness direction z. The connecting portion 45 is electrically connected to the connecting member 52. The shape of the connecting portion 45 is not limited; in the illustrated example, it has a long rectangular shape extending in the first direction x. As viewed in the thickness direction z, the connecting portion 45 is smaller than the pad portion 25. The connecting portion 45 has a smaller size than the pad portion 25 in the thickness direction z, while having the same size as the terminal portion 29.

The second member 4 of this embodiment includes a second side surface 43, which is located between the second obverse surface 41 and the second reverse surface 42 in the thickness direction z and is arranged to face the second side y2 in the second direction y.

As shown in FIGS. 28 and 29, the second reverse surface 42 includes a second reverse surface flat portion 42a and a second reverse surface recessed portion 42c. The second reverse surface flat portion 42a is a flat region facing the second side z2 in the thickness direction z. The second reverse surface recessed portion 42c is a portion sunk toward the first side z1 in the thickness direction z relative to the second reverse surface flat portion 42a. The second reverse surface recessed portion 42c may be located on the first side z1 in the thickness direction z relative to the region of the second reverse surface flat portion 42a that is adjacent to the second reverse surface recessed portion 42c. In the illustrated example, as viewed in the thickness direction z, the second reverse surface recessed portion 42c is provided at an outer edge of the second reverse surface 42. The second reverse surface recessed portion 42c is in contact with the second side surface 43. The shape of the second reverse surface recessed portion 42c is not limited. In the example shown in FIG. 29, the second reverse surface recessed portion 42c is a convex curved surface connecting to the second side surface 43 and to the second reverse surface flat portion 42a.

The second obverse surface 41 includes a second obverse surface flat portion 41a and a second obverse surface projecting portion 41c. In this embodiment, the second obverse surface 41 may correspond to the “second surface,” the second obverse surface flat portion 41a may correspond to the “second flat portion,” and the second obverse surface projecting portion 41c may correspond to the “second projecting portion.” The second obverse surface flat portion 41a is a flat region facing the first side z1 in the thickness direction z. The second obverse surface projecting portion 41c projects toward the first side z1 in the thickness direction z relative to the second obverse surface flat portion 41a. The second obverse surface projecting portion 41c may project toward the first side z1 in the thickness direction z relative to the region of the second obverse surface flat portion 41a that is adjacent to the second obverse surface projecting portion 41c. In the illustrated example, the second obverse surface projecting portion 41c is provided at an outer edge of the second obverse surface 41 as viewed in the thickness direction z. The second obverse surface projecting portion 41c is in contact with the second side surface 43. The shape of the second obverse surface projecting portion 41c is not limited. In the example shown in FIG. 29, the second obverse surface projecting portion 41c has a shape made up of a first surface extending from the second side surface 43 to a first side z1 in the thickness direction z, and a concave curved surface connecting to the tip of the first surface at the first side z1 and connecting to the second obverse surface flat portion 41a.

The plurality of terminal portions 46 are arranged side by side in the first direction x. Each terminal portion 46 includes a root portion 461, a front end portion 463, and a bent portion 462. Each terminal portion 46 is bent toward the first side z1 in the thickness direction z with respect to the root portion 461.

The root portions 461 are connected to the connecting portion 45, and each root portion 461 extends from the connecting portion 45 toward the first side y1 in the second direction y. In the illustrated example, the root portions 461 are parallel to the x-y plane. The shape of each root portion 461 is not limited; in the illustrated example, each root portion 461 has a rectangular shape as viewed in the thickness direction z.

The front end portions 463 are located on the first side z1 in the thickness direction z relative to the root portions 461. The front end portions 463 are used in surface-mounting the electronic device A200 onto a circuit board or the like. The front end portions 463 each extend in the second direction y.

The bent portions 462 are interposed between the root portions 461 and the front end portions 463, respectively. The bent portions 462 extend from the root portions 461 toward the first side z1 in the thickness direction z. In the illustrated example, the bent portions 462 are inclined relative to the thickness direction z (in y-z plane). The shape of the bent portions 462 is not limited; in the illustrated example, they are rectangular as viewed in the second direction y.

The second member 3A is spaced apart from the first member 2 and the second member 4, and is positioned on the first side y1 of the second direction y relative to the pad portion 25. The second member 3A is aligned with the second member 4 in the first direction x. The second member 3A includes a second obverse surface 31 and a second reverse surface 32. The second member 3A also includes a connecting portion 35 and a terminal portion 36.

The second obverse surface 31 faces the first side z1 in the thickness direction z. The second reverse surface 32 faces the second side z2 in the thickness direction z. The connecting portion 35 is electrically connected to the connecting member 51. The shape of the connecting portion 35 is not limited; in the illustrated example, it is rectangular as viewed in the thickness direction z. As viewed in the thickness direction z, the connecting portion 35 is smaller, e.g., in area or length, than the connecting portion 45. The connecting portion 35 is smaller in size than the pad portion 25 in the thickness direction z, while having the same size as the connecting portion 45.

The second member 3A of this embodiment includes a second side surface 33. The second side surface 33 is located between the second obverse surface 31 and the second reverse surface 32 in the thickness direction z and faces the second side y2 in the second direction y.

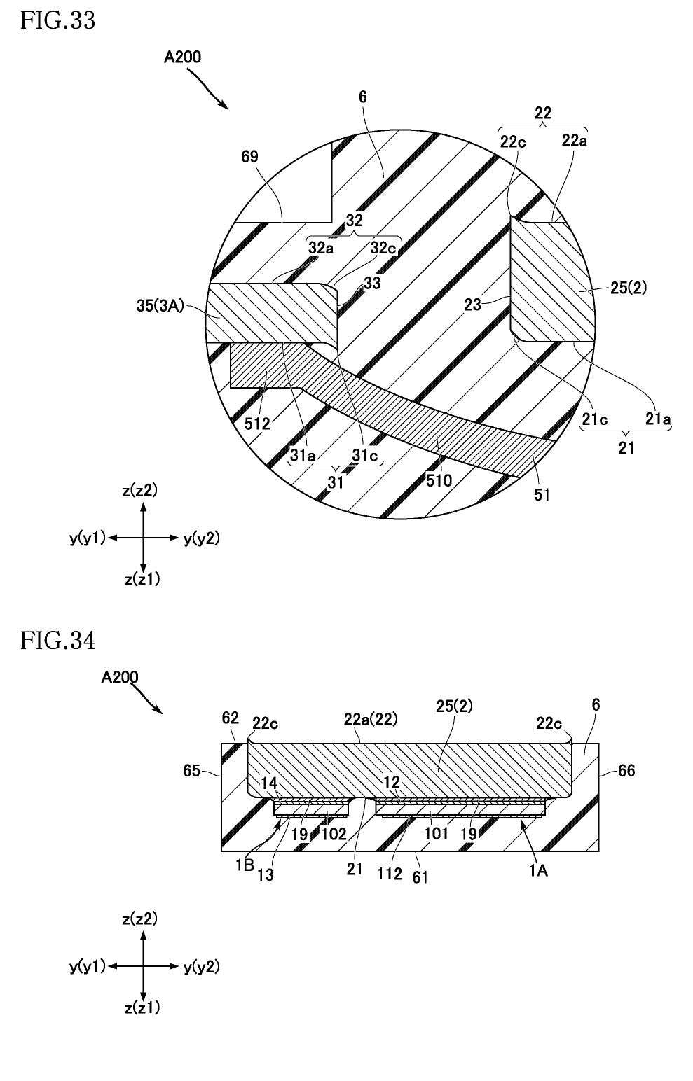

As shown in FIGS. 32 and 33, the second reverse surface 32 includes a second reverse surface flat portion 32a and a second reverse surface recessed portion 32c. The second reverse surface flat portion 32a is a flat region facing the second side z2 in the thickness direction z. The second reverse surface recessed portion 32c is a portion sunk toward the first side z1 in the thickness direction z relative to the second reverse surface flat portion 32a. The second reverse surface recessed portion 32c may be located on the first side z1 in the thickness direction z relative to the region of the second reverse surface flat portion 32a that is adjacent to the second reverse surface recessed portion 32c. In the illustrated example, as viewed in the thickness direction z, the second reverse surface recessed portion 32c is provided at an outer edge of the second reverse surface 32. The second reverse surface recessed portion 32c is in contact with the second side surface 33. The shape of the second reverse surface recessed portion 32c is not limited. In the example shown in FIG. 33, the second reverse surface recessed portion 32c is a convex curved surface connecting to the second side surface 33 and to the second reverse surface flat portion 32a.

The second obverse surface 31 includes a second obverse surface flat portion 31a and a second obverse surface projecting portion 31c. In this embodiment, the second obverse surface 31 may correspond to the “second surface,” the second obverse surface flat portion 31a may correspond to the “second flat portion,” and the second obverse surface projecting portion 31c may correspond to the “second projecting portion.” The second obverse surface flat portion 31a is a flat region facing the first side z1 in the thickness direction z. The second obverse surface projecting portion 31c projects toward the first side z1 in the thickness direction z relative to the second obverse surface flat portion 31a. The second obverse surface projecting portion 31c may only project toward the first side z1 in the thickness direction z relative to the region of the second obverse surface flat portion 31a that is adjacent to the second obverse surface projecting portion 31c. In the illustrated example, as viewed in the thickness direction z, the second obverse surface projecting portion 31c is provided at an outer edge of the second obverse surface 31. The second obverse surface projecting portion 31c is in contact with the second side surface 33. The shape of the second obverse surface projecting portion 31c is not limited. In the example shown in FIG. 33, the second obverse surface projecting portion 31c has a shape made up of a first surface extending from the second side surface 33 toward the first side z1 in the thickness direction z, and a concave curved surface connecting to the tip of the first surface on the first side z1 and connecting to the second obverse surface flat portion 31a.

The terminal portion 36 includes a root portion 361, a front end portion 363, and a bent portion 362. The terminal portion 36 is bent toward the first side z1 in the thickness direction z with respect to the root portion 361.

The root portion 361 is connected to the connecting portion 35 and extends from the connecting portion 35 toward the first side y1 in the second direction y. In the illustrated example, the root portion 361 is parallel to the x-y plane. The shape of the root portion 361 is not limited; in the illustrated example, it is rectangular as viewed in the thickness direction z.

The front end portion 363 is located on the first side z1 in the thickness direction z relative to the root portion 361. The front end portion 363 is used in surface-mounting the electronic device A200 onto a circuit board or the like. The front end portion 363 extends in the second direction y.

The bent portion 362 is located between the root portion 361 and the front end portion 363. The bent portion 362 extends from the root portion 361 toward the first side z1 in the thickness direction z. In the illustrated example, the bent portion 362 is inclined relative to the thickness direction z (in the y-z plane). The shape of the bent portion 362 is not limited; in the illustrated example, it is rectangular as viewed in the second direction y.

The second member 3B is spaced apart from the first member 2, the second member 4, and the second member 3A, and located on the first side y1 of the second direction y relative to the pad portion 25. The second member 3B is located between the second member 4 and the second member 3A in the first direction x. The second member 3B includes a second obverse surface 31 and a second reverse surface 32. The second member 3B also includes a connecting portion 35 and a terminal portion 36.

The second obverse surface 31 faces the first side z1 in the thickness direction z. The second reverse surface 32 faces the second side z2 in the thickness direction z. The connecting member 53 is electrically connected to the connecting portion 35. The shape of the connecting portion 35 is not limited; in the illustrated example, it is rectangular as viewed in the thickness direction z. As viewed in the thickness direction z, the connecting portion 35 is smaller than the connecting portion 45 and is approximately the same size as the connecting portion 35 in the thickness direction z. The connecting portion 35 is smaller in size than the pad portion 25 in the thickness direction z and is the same as each of the connecting portion 45 and the connecting portion 35.

The second member 3B of this embodiment includes a second side surface 33. The second side surface 33 is positioned between the second obverse surface 31 and the second reverse surface 32 in the thickness direction z and faces the second side y2 in the second direction y.

As shown in FIGS. 32 and 33, the second reverse surface 32 includes a second reverse surface flat portion 32a and a second reverse surface recessed portion 32c. The second reverse surface flat portion 32a is a flat region facing the second side z2 in the thickness direction z. The second reverse surface recessed portion 32c is sunk toward the first side z1 in the thickness direction z relative to the second reverse surface flat portion 32a. The second reverse surface recessed portion 32c may be located on the first side z1 in the thickness direction z, relative to the portion of the second reverse surface flat portion 32a that is adjacent to the second reverse surface recessed portion 32c. In the illustrated example, as viewed in the thickness direction z, the second reverse surface recessed portion 32c is provided at an outer edge of the second reverse surface 32. The second reverse surface recessed portion 32c is in contact with the second side surface 33. The shape of the second reverse surface recessed portion 32c is not limited. In the example shown in FIG. 33, the second reverse surface recessed portion 32c is a convex curved surface connecting to the second side surface 33 and to the second reverse surface flat portion 32a.

The second obverse surface 31 includes a second obverse surface flat portion 31a and a second obverse surface projecting portion 31c. In this embodiment, the second obverse surface 31 may correspond to the “second surface,” the second obverse surface flat portion 31a may correspond to the “second flat portion,” and the second obverse surface projecting portion 31c may correspond to the “second projecting portion.” The second obverse surface flat portion 31a is a flat region facing the first side z1 in the thickness direction z. The second obverse surface projecting portion 31c projects toward the first side z1 in the thickness direction z relative to the second obverse surface flat portion 31a. The second obverse surface projecting portion 31c may protrude toward the first side z1 in the thickness direction z relative to the portion of the second obverse surface flat portion 31a that is adjacent to the second obverse surface projecting portion 31c. In the illustrated example, the second obverse surface projecting portion 31c is provided at an outer edge of the second obverse surface 31 as viewed in the thickness direction z. The second obverse surface projecting portion 31c is in contact with the second side surface 33. The shape of the second obverse surface projecting portion 31c is not limited. In the example shown in FIG. 33, the second obverse surface projecting portion 31c has a shape made up of a first surface extending from the second side surface 33 to the first side z1 in the thickness direction z, and a concave curved surface connecting to the tip of the first surface on the first side z1 and to the second obverse surface flat portion 31a.

The terminal portion 36 includes a root portion 361, a front end portion 363, and a bent portion 362. The terminal portion 36 is bent toward the first side z1 in the thickness direction z with respect to the bent portion 362.

The root portion 361 is connected to the connecting portion 35 and extends from the connecting portion 35 toward the first side y1 in the second direction y. In the illustrated example, the root portion 361 is parallel to the x-y plane. The shape of the root portion 361 is not limited; in the illustrated example, it is rectangular as viewed in the thickness direction z.

The front end portion 363 is positioned on the first side z1 in the thickness direction z relative to the root portion 361. The front end portion 363 is used in surface mounting the electronic device A200 onto a circuit board or the like. The front end portion 363 extends in the second direction y.

The bent portion 362 is located between the root portion 361 and the front end portion 363. The bent portion 362 extends from the root portion 361 toward the first side z1 in the thickness direction z. In the illustrated example, the bent portion 362 is inclined relative to the thickness direction z (in the y-z plane). The shape of the bent portion 362 is not limited; in the illustrated example, the bent portion 362 is rectangular as viewed in the second direction y.

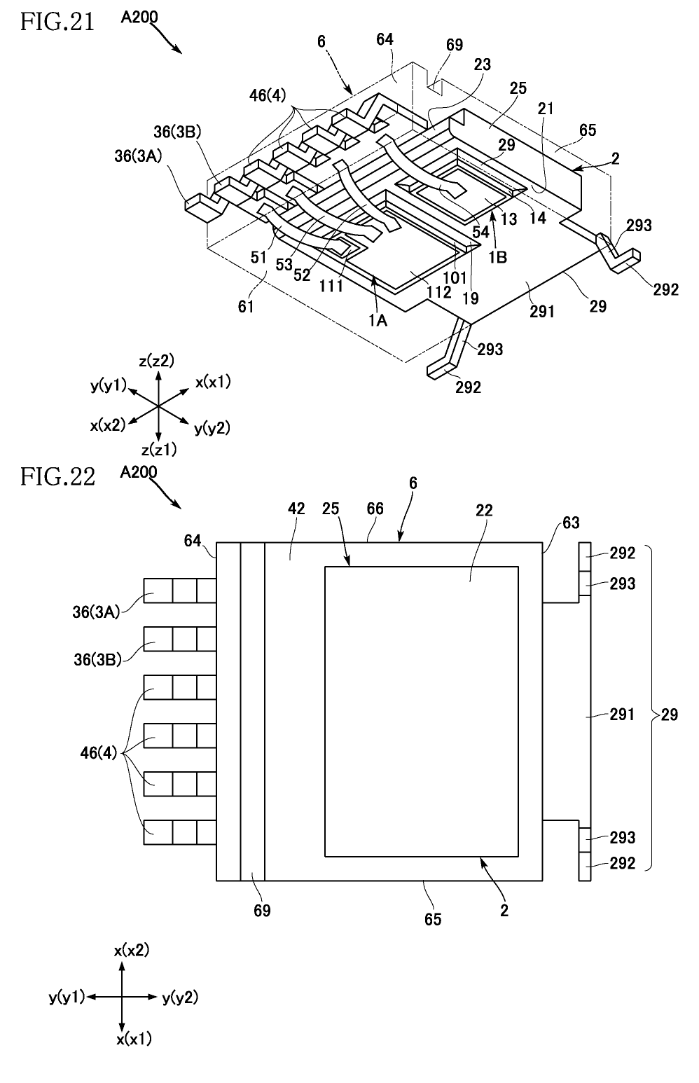

The electronic element 1A is mounted on the first obverse surface 21 of the pad portion 25, as shown in FIGS. 21 and 27 to 34. In the electronic device A200, the electronic element 1A is a switching element. The switching element is, for example, an n-channel, vertical-structure MOSFET (Metal-Oxide-Semiconductor Field-Effect Transistor). The electronic element 1A is not limited to a MOSFET. The electronic element 1A may be a transistor such as an IGBT (Insulated Gate Bipolar Transistor). The semiconductor element 1A includes a semiconductor layer 101, a source electrode 112, a drain electrode 12, and a gate electrode 111.

The semiconductor layer 101 includes a compound semiconductor substrate. The main material of the compound semiconductor substrate is silicon carbide (SiC). Alternatively, silicon (Si) may be used as the main material of the compound semiconductor substrate.

The source electrode 112 is provided on the semiconductor layer 101 on the first side z1 (the side the first obverse surface 21 faces in the thickness direction z) in the thickness direction z.

The drain electrode 12 is provided opposite from the source electrode 112 in the thickness direction z. The drain electrode 12 faces the first obverse surface 21 of the pad portion 25 of the first member 2. In this embodiment, the drain electrode 12 is conductively bonded to the first obverse surface 21 via a conductive bonding material 19. The conductive bonding material 19 is, for example, solder, silver (Ag) paste, or sintered silver.

The gate electrode 111 is disposed on the same side as the source electrode 112 in the thickness direction z and is spaced apart from the source electrode 112. As viewed in the thickness direction z, the area of the gate electrode 111 is smaller than the area of the source electrode 112.

The electronic element 1B is mounted on the first obverse surface 21 of the pad portion 25. The electronic element 1B is located relative to the electronic element 1A on the first side x1 in the first direction x. In the electronic device A200, the electronic element 1B is a diode. The electronic element 1B includes a semiconductor layer 102, an obverse surface electrode 13, and a reverse surface electrode 14.

The semiconductor layer 102 includes a compound semiconductor substrate. The main material of the compound semiconductor substrate is silicon carbide (SiC). Alternatively, silicon (Si) may be used as the main material of the compound semiconductor substrate.

The obverse surface electrode 13 is provided on the semiconductor layer 102 on the first side z1 (the side the first obverse surface 21 faces in the thickness direction z) in the thickness direction z. The obverse surface electrode 13 may correspond to the anode electrode of the electronic element 1B.

The reverse surface electrode 14 is provided opposite from the obverse surface electrode 13 in the thickness direction z. The reverse surface electrode 14 faces the first obverse surface 21 of the pad portion 25 of the first member 2. The reverse surface electrode 14 may correspond to the cathode electrode of the electronic element 1B. In this embodiment, the reverse surface electrode 14 is conductively bonded to the first obverse surface 21 via the conductive bonding material 19.

The connecting member 52 is electrically bonded to the source electrode 112 of the electronic element 1A and to the second obverse surface 41 of the connecting portion 45 of the second member 4. The material of the connecting member 52 is not limited and may include metals such as aluminum (Al), copper (Cu), and gold (Au). In this embodiment, the connecting member 52 is a wire containing aluminum (Al) and has a relatively large diameter to carry high currents. The diameter of the connecting member 52 is not limited but is, for example, approximately 400 to 500 μm. The number of connecting members 52 is not limited; two or more connecting members 52 may be used.

As shown in FIGS. 28 and 29, the connecting member 52 includes a bonding portion 521, a bonding portion 522, and a loop portion 520. The bonding portion 521 is connected to the source electrode 112 of the electronic element 1A. The bonding portion 522 is connected to the connecting portion 45. In this embodiment, the source electrode 112 to which the bonding portion 521 is connected is located on the first side z1 (opposite side) in the thickness direction z relative to the second obverse surface 41 of the connecting portion 45 to which the bonding portion 522 is connected. The loop portion 520 extends between the bonding portion 521 and the other bonding portion 522 and has a shape bulging toward the z1 side in the thickness direction z.

The connecting member 51 is electrically bonded to the gate electrode 111 of the electronic element 1A and to the second obverse surface 31 of the connecting portion 35 of the second member 3A. The material and diameter of the connecting member 51 are not limited. In the present embodiment, the connecting member 51 is the same wire as used for the connecting member 52.

As shown in FIGS. 32 and 33, the connecting member 51 includes a bonding portion 511, a bonding portion 512, and a loop portion 510. The bonding portion 511 is connected to the gate electrode 111 of the electronic element 1A. The bonding portion 512 is connected to the connecting portion 35. In this embodiment, the gate electrode 111 to which the bonding portion 511 is connected is located on the first side z1 (opposite side) in the thickness direction z relative to the second obverse surface 31 of the connecting portion 35 to which the bonding portion 512 is connected. The loop portion 510 extends between the bonding portion 511 and the other bonding portion 512 and has a shape bulging toward the z1 side in the thickness direction z.

The connecting member 53 is electrically bonded to the source electrode 112 of the electronic element 1A and the second obverse surface 31 of the connecting portion 35 of the second member 3B. The material and diameter of connecting member 53 are not limited. In this embodiment, the connecting member 53 is the same wire as used for the connecting member 52.

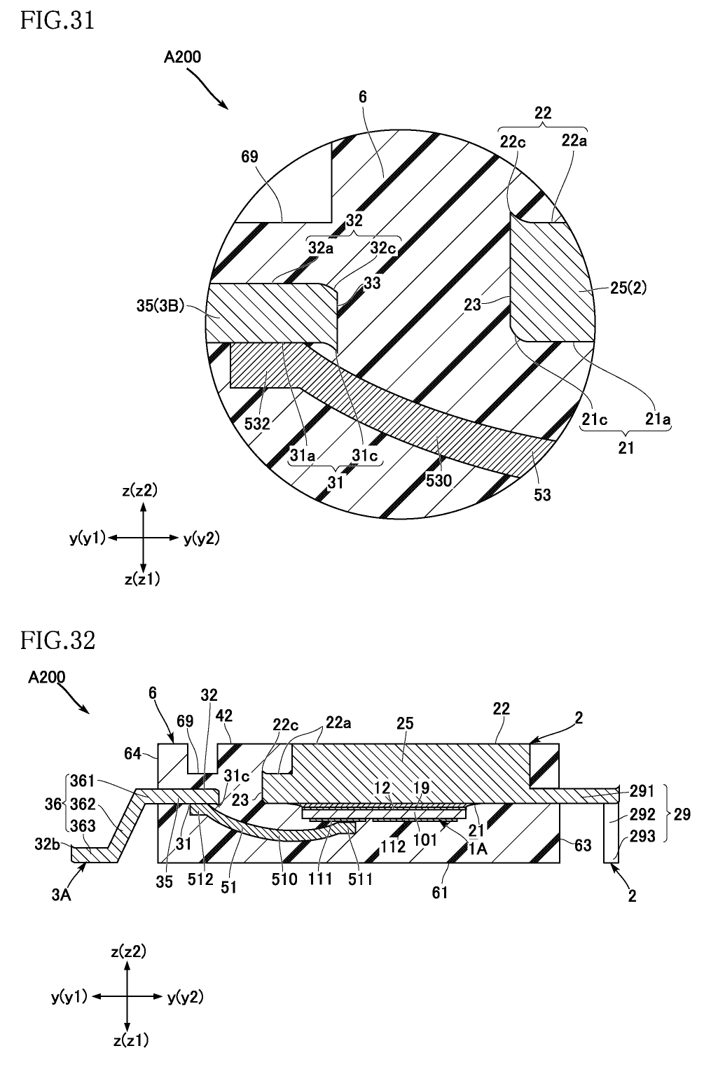

As shown in FIGS. 30 and 31, the connecting member 53 includes a bonding portion 531, a bonding portion 532, and a loop portion 530. The bonding portion 531 is connected to the source electrode 112 of the electronic element 1A. The bonding portion 532 is connected to the connecting portion 35. In this embodiment, the source electrode 112 to which bonding portion 531 is connected is located on the first side z1 (opposite side) in the thickness direction z relative to the second obverse surface 31 of the connecting portion 35 to which the bonding portion 532 is connected. The loop portion 530 extends between the bonding portion 531 and the bonding portion 532 and has a shape bulging toward the z1 side in the thickness direction z.

The connecting member 54 is electrically bonded to the obverse surface electrode 13 of the electronic element 1B and the second obverse surface 41 of the connecting portion 45 of the second member 4. The material and diameter of the connecting member 54 are not limited. In this embodiment, the connecting member 54 is the same wire as used for the connecting member 52.

The connecting member 54 may have portions similar to, for example, the bonding portion 521, the bonding portion 522, and the loop portion 520 of the connecting member 52.

In this embodiment, the terminal portion 29 of the first member 2 is a drain terminal, the terminal portion 46 of the second member 4 is a source terminal, the terminal portion 36 of the second member 3A is a gate terminal, and the terminal portion 36 of the second member 3B is a source sense terminal.

The sealing resin 6 covers the electronic element 1A, the electronic element 1B, the connecting members 51 to 54, and parts of the first member 2 and second members 4, 3A, 3B, as shown in FIGS. 17 to 34. The sealing resin 6 has electrical insulating properties. The sealing resin 6 is made of a material including, for example, a black epoxy resin. The sealing resin 6 includes a resin obverse surface 61, a resin reverse surface 62, and resin side surfaces 63 to 66.

The resin obverse surface 61 faces the first side z1 in the thickness direction z (the same side as the first obverse surface 21 in the thickness direction z). The resin reverse surface 62 faces the second side z2 in the thickness direction z (the opposite side from the resin obverse surface 61 in the thickness direction z). The first reverse surface 22 of the pad portion 25 of the first member 2 is exposed from the resin reverse surface 62. The resin reverse surface 62 is flush with a portion of the first reverse surface flat portion 22a of the first reverse surface 22. The first reverse surface 22 is spaced apart from the resin side surface 63 in the second direction y.

The resin side surface 63 faces the second side y2 in the second direction y. The first part 291 of the terminal portion 29 of the first member 2 extends through and out of the resin side surface 63. The first part 291 is spaced apart from the resin reverse surface 62 in the thickness direction z.

The resin side surface 64 faces the first side y1 in the second direction y (the side opposite from the resin side surface 63 in the second direction y). In this embodiment, the root portions 461 of the plurality of terminal portions 46 of the second member 4, the root portion 361 of the terminal portion 36 of the second member 3A, and the root portion 361 of the terminal portion 36 of the second member 3B extend through and out of the resin side surface 64. The root portions 461, 361 are spaced apart from the resin reverse surface 62 in the thickness direction z.

The resin side surface 65 and the resin side surface 66 face away from each other in the first direction x.

In the illustrated example, the sealing resin 6 includes a depression or groove 69. The groove 69 is a part recessed in the thickness direction z with respect to the resin reverse surface 62. In the illustrated example, the grove 69 extends in the first direction x and reaches the resin side surface 65 and the resin side surface 66.

Next, the advantages of the electronic device A200 are described below.

The present embodiment also enables the realization of a more appropriate package structure for the electronic device A200.

As shown in FIGS. 28, 30, 32, the gate electrode 111 (connected to the bonding portion 511) and the source electrode 112 (connected to the bonding portions 521, 531) are located on the first side z1 (opposite side) in the thickness direction z relative to the second obverse surface 31 of the connecting portion 35 (to which the bonding portion 532 is connected) and the second obverse surface 41 of the connecting portion 45 (to which the bonding portion 522 is connected). Thus, the spacing in the thickness direction z between the loop portions 510, 520, 530 and the second obverse surfaces 31, 41 can be appropriately large. Accordingly, the second obverse surface projecting portions 31c, 41c are less likely to interfere with the loop portions 510, 520, 530. In the illustrated example, since the second obverse surface projecting portion 31c or 41c (“the second projecting portion”) is provided on the second obverse surface 31 or 41, it is possible to ensure an appropriately large area of second obverse surface flat portion 31a or 41a in the second obverse surface 31 or 41. On the other hand, in the second reverse surface 32 or 42, which includes the second reverse surface recessed portion 32c or 42c, the area of the second reverse surface flat portion 32a or 42a tends to be small. In light of this, use is made of the second obverse surfaces 31 and 41, which can provide a larger area, for the bonding of the bonding portion 511 or 521 or 531, so that an appropriately large bonding area is ensured.

### FIRST VARIATION OF SECOND EMBODIMENT:

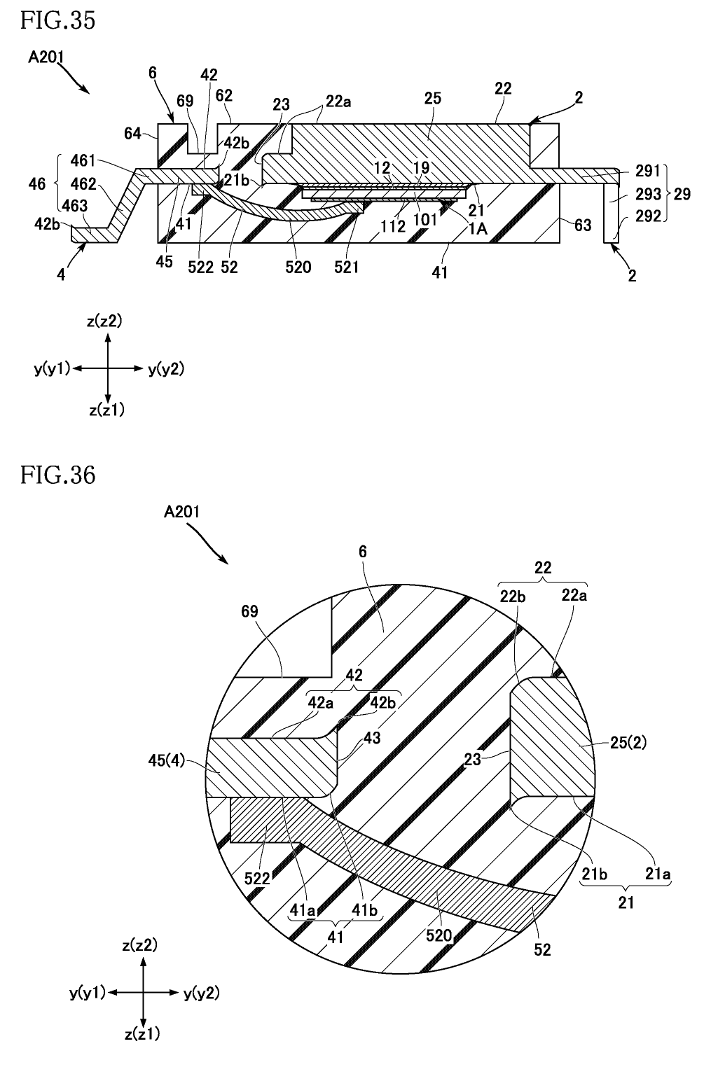

FIGS. 35 to 41 illustrate a first variation of the electronic device A200 of the present disclosure. In the electronic device A201 of this variation, the first obverse surface 21 includes a first obverse surface flat portion 21a and a first obverse surface projecting portion 21b. In this variation, the first obverse surface 21 may correspond to a “first surface,” the first obverse surface flat portion 21a may correspond to a “first flat portion,” and the first obverse surface projecting portion 21b may correspond to a “first projecting portion.” In this variation, the first side z1 in the thickness direction z may correspond to “one/first side,” and the second side z2 may correspond to “other/second/opposite side.” The first obverse surface flat portion 21a is a flat region facing the first side z1 in the thickness direction z. The first obverse surface projecting portion 21b projects toward the first side z1 in the thickness direction z relative to the first obverse surface flat portion 21a. The first obverse surface projecting portion 21b may project toward the first side z1 in the thickness direction z relative to the portion of the first obverse surface flat portion 21a that is adjacent to the first obverse surface projecting portion 21b. In the illustrated example, as viewed in the thickness direction z, the first obverse surface projecting portion 21b is provided at an outer edge of the first obverse surface 21. The first obverse surface projecting portion 21b is in contact with the first side surface 23. The shape of the first obverse surface projecting portion 21b is not limited. In the examples shown in FIGS. 36, 38, and 40, the first obverse surface projecting portion 21b has a shape made up of a first surface extending from the first side surface 23 in the thickness direction z on the first side z1, and a concave curved surface connecting to the tip of the first surface on the first side z1 and connecting to the first obverse surface flat portion 21a.

The first reverse surface 22 includes a first reverse surface flat portion 22a and a first reverse surface recessed portion 22b. The first reverse surface flat portion 22a is a flat region facing the second side z2 in the thickness direction z. In the illustrated example, the first reverse surface flat portion 22a is divided into two or more regions. The first reverse surface recessed portion 22b is sunk toward the first side z1 in the thickness direction z relative to the first reverse surface flat portion 22a. The first reverse surface recessed portion 22b may be located on the first side z1 in the thickness direction z, relative to the portion of the first reverse surface flat portion 22a that is adjacent to the first reverse surface recessed portion 22b. In the illustrated example, as viewed in the thickness direction z, the first reverse surface recessed portion 22b is provided at an outer edge of the first reverse surface 22. The first reverse surface recessed portion 22b is in contact with the first side surface 23. The shape of the first reverse surface recessed portion 22b is not limited. In the examples shown in FIGS. 36, 38, and 40, the first reverse surface recessed portion 22b is a convex curved surface connecting to the first side surface 23 and to the first reverse surface flat portion 22a.

As shown in FIGS. 35 and 36, the second obverse surface 41 includes a second obverse surface flat portion 41a and a second obverse surface recessed portion 41b. The second obverse surface flat portion 41a is a flat region facing the first side z1 in the thickness direction z. The second obverse surface recessed portion 41b is sunk toward the second side z2 in the thickness direction z relative to the second obverse surface flat portion 41a. The second obverse surface recessed portion 41b may be located on the second side z2 in the thickness direction z relative to the portion of the second obverse surface flat portion 41a that is adjacent to the second obverse surface recessed portion 41b. In the illustrated example, as viewed in the thickness direction z, the second obverse surface recessed portion 41b is provided at an outer edge of the second obverse surface 41. The second obverse surface recessed portion 41b is in contact with the second side surface 43. The shape of the second obverse surface recessed portion 41b is not limited. In the example shown in FIG. 36, the second obverse surface recessed portion 41b is a convex curved surface connecting to the second side surface 43 and to the second obverse surface flat portion 41a.

The second reverse surface 42 includes a second reverse surface flat portion 42a and a second reverse surface projecting portion 42b. In this variation, the second reverse surface 42 may correspond to the “second surface,” the second reverse surface flat portion 42a may correspond to the second flat portion, and the second reverse surface projecting portion 42b may correspond to the second projecting portion. The second reverse surface flat portion 42a is a flat region facing the second side z2 in the thickness direction z. The second reverse surface projecting portion 42b projects toward the second side z2 in the thickness direction z relative to the second reverse surface flat portion 42a.

The second reverse surface projecting portion 42b may protrude to the second side z2 in the thickness direction z relative to the portion of the second reverse surface flat portion 42a that is adjacent to the second reverse surface projecting portion 42b. In the illustrated example, as viewed in the thickness direction z, the second reverse surface projecting portion 42b is provided at an outer edge of the second reverse surface 42. The second reverse surface projecting portion 42b is in contact with the second side surface 43. The shape of the second reverse surface projecting portion 42b is not limited. In the example shown in FIG. 36, the second reverse surface projecting portion 42b has a shape made up of a first surface extending from the second side surface 43 toward the second side z2 in the thickness direction z, and a concave curved surface connecting the tip of the first surface on the second side z2 and connecting to the second reverse surface flat portion 42a.

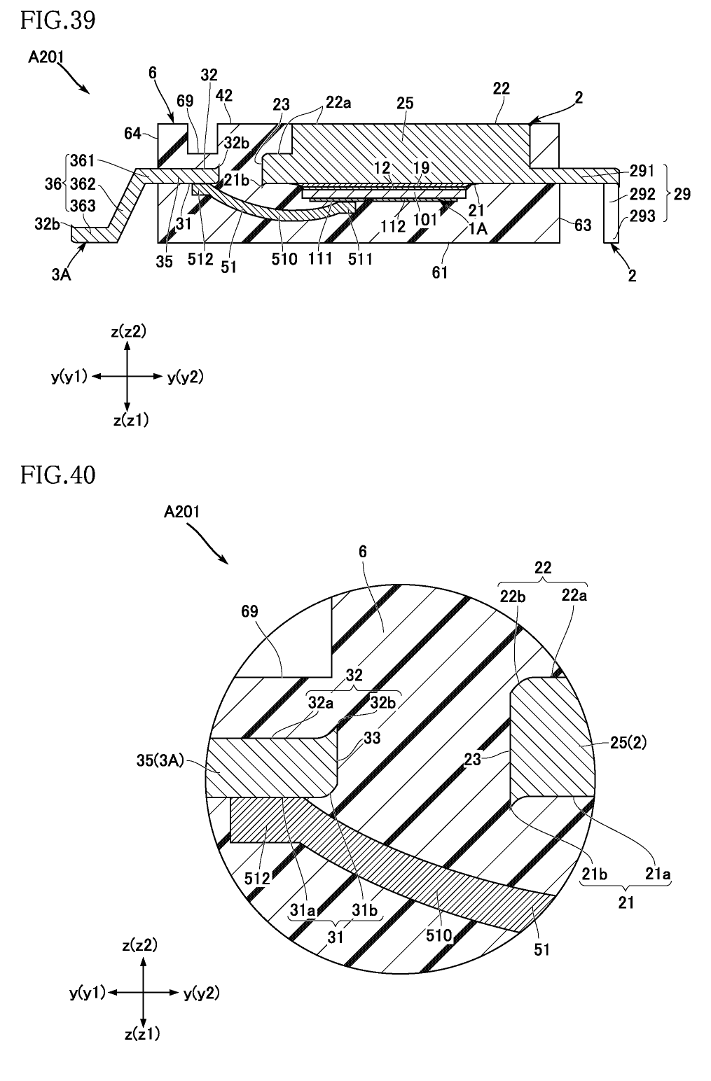

As shown in FIGS. 39 and 40, the second obverse surface 31 of the second member 3A includes a second obverse surface flat portion 31a and a second obverse surface recessed portion 31b. The second obverse surface flat portion 31a is a flat region facing the first side z1 in the thickness direction z. The second obverse surface recessed portion 31b is sunk toward the second side z2 in the thickness direction z relative to the second obverse surface flat portion 31a. The second obverse surface recessed portion 31b may be located on the second side z2 in the thickness direction z, relative to the portion of the second obverse surface flat portion 31a that is adjacent to the second obverse surface recessed portion 31b. In the illustrated example, as viewed in the thickness direction z, the second obverse surface recessed portion 31b is provided at an outer edge of the second obverse surface 31. The second obverse surface recessed portion 31b is in contact with the second side surface 33. The shape of the second obverse surface recessed portion 31b is not limited. In the example shown in FIG. 40, the second obverse surface recessed portion 31b is a convex curved surface connecting to the second side surface 33 and to the second obverse surface flat portion 31a.

The second reverse surface 32 of the second member 3A includes a second reverse surface flat portion 32a and a second reverse surface projecting portion 32b. In this variation, the second reverse surface 32 may correspond to the “second surface,” the second reverse surface flat portion 32a may correspond to the second flat portion, and the second reverse surface projecting portion 32b may correspond to the second projecting portion. The second reverse surface flat portion 32a is a flat region facing the second side z2 in the thickness direction z. The second reverse surface projecting portion 32b projects toward the second side z2 in the thickness direction z relative to the second reverse surface flat portion 32a. The second reverse surface projecting portion 32b may project toward the second side z2 in the thickness direction z relative to the portion of the second reverse surface flat portion 32a that is adjacent to the second reverse surface projecting portion 32b. In the illustrated example, as viewed in the thickness direction z, the second reverse surface projecting portion 32b is provided at an outer edge of the second reverse surface 32. The second reverse surface projecting portion 32b is in contact with the second side surface 33. The shape of the second reverse surface projecting portion 32b is not limited. In the example shown in FIG. 40, the second reverse surface projecting portion 32b has a shape made up of a first surface extending from the second side surface 33 to the second side z2 in the thickness direction z, and a concave curved surface connecting to the tip of the first surface on the second side z2 and connecting to the second reverse surface flat portion 32a.

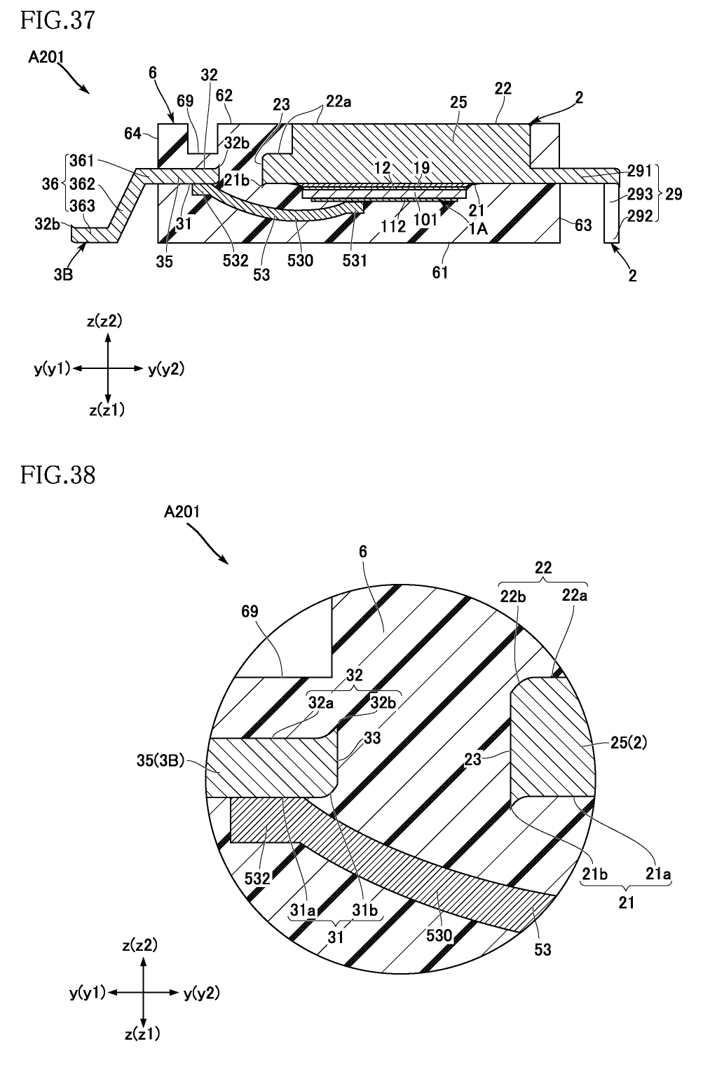

As shown in FIGS. 37 and 38, the second obverse surface 31 of the second member 3B includes a second obverse surface flat portion 31a and a second obverse surface recessed portion 31b. The second obverse surface flat portion 31a is a flat region facing the first side z1 in the thickness direction z. The second obverse surface recessed portion 31b is sunk toward the second side z2 in the thickness direction z relative to the second obverse surface flat portion 31a. The second obverse surface recessed portion 31b may be located on the second side z2 in the thickness direction z, relative to the portion of the second obverse surface flat portion 31a that is adjacent to the second obverse surface recessed portion 31b. In the illustrated example, as viewed in the thickness direction z, the second obverse surface recessed portion 31b is provided at an outer edge of the second obverse surface 31. The second obverse surface recessed portion 31b is in contact with the second side surface 33. The shape of the second obverse surface recessed portion 31b is not limited. In the example shown in FIG. 38, the second obverse surface recessed portion 31b is a convex curved surface connecting to the second side surface 33 and to the second obverse surface flat portion 31a.

The second reverse surface 32 of the second member 3B includes a second reverse surface flat portion 32a and a second reverse surface projecting portion 32b. In this variation, the second reverse surface 32 may correspond to the “second surface,” the second reverse surface flat portion 32a may correspond to the second flat portion, and the second reverse surface projecting portion 32b may correspond to the second projecting portion. The second reverse surface flat portion 32a is a flat region facing the second side z2 in the thickness direction z. The second reverse surface projecting portion 32b projects toward the second side z2 in the thickness direction z relative to the second reverse surface flat portion 32a. The second reverse surface projecting portion 32b may project toward the second side z2 in the thickness direction z relative to the portion of the second reverse surface flat portion 32a that is adjacent to the second reverse surface projecting portion 32b. In the illustrated example, as viewed in the thickness direction z, the second reverse surface projecting portion 32b is provided at an outer edge of the second reverse surface 32. The second reverse surface projecting portion 32b is in contact with the second side surface 33. The shape of the second reverse surface projecting portion 32b is not limited. In the example shown in FIG. 38, the second reverse surface projecting portion 32b has a shape made up of a first surface extending from the second side surface 33 to the second side z2 in the thickness direction z, and a concave curved surface connecting to the tip of the first surface on the second side z2 and connecting to the second reverse surface flat portion 32a.

FIG. 42 shows how the electronic device A201 (or A200) can be used. In this example, the electronic device A201 is surface-mounted on a circuit board 92. The second parts 292 of the terminal portion 29, the front end portions 463 of the terminal portions 46, the front end portions 363 of the terminal portions 36 are electrically connected to the wiring patterns (not shown) of the circuit board 92, for example, by solder 921. A heat sink 91 is disposed on the first reverse surface 22 (first reverse surface 22a) of the pad portion 25. In the illustrated example, a sheet material 919 is disposed between the first reverse surface 22 and the heat sink 91. The sheet material 919 is, for example, an insulating sheet.

Next, the advantages of the electronic device A201 are described below.

This variation also can prevent connection failures such as wire breaks in connecting the connecting member 51 to the second obverse surface 31, while also achieving the same effects as the electronic device A100.

As shown in FIGS. 35, 37 and 39, the second reverse surface projecting portions 32b, 42b protrude toward the second side z2 in the thickness direction z in the front end portions 363 of the second members 3A, 3B and the front end portions 463 of the second member 4. This allows the second reverse surface projecting portions 32b and 42b to avoid interfering with the circuit board 92, which is disposed on the first side z1 in the thickness direction z relative to the front end portions 363, 463, as shown in FIG. 42. Accordingly, the electronic device A201 can be properly mounted on the circuit board 92.

The electronic device and method of manufacturing the electronic device according to the present disclosure are not limited to the embodiments/variations described above. The configurations of the electronic device and the method of manufacturing the electronic device described herein may be modified in various ways.

Clause 1. An electronic device comprising:

a first member including a first surface facing one side in a thickness direction;

an electronic element mounted on the first member;

a connecting member electrically connected to the electronic element;

a second member including a second surface facing an opposite side in the thickness direction, the second member including a terminal portion and a connecting portion to which the connecting member is connected; and

a sealing resin covering a part of the first member, a part of the second member, the electronic element and the connecting member,

wherein the first surface includes a first flat portion and a first projecting portion,

the first projecting portion projects toward the one side with respect to the first flat portion,

the second surface includes a second flat portion and a second projecting portion, and

the second projecting portion projects toward the opposite side with respect to the second flat portion.

Clause 2. The electronic device according to clause 1, wherein the one side is referred to as a first side; the opposite side is referred to as a second side; the first surface is referred to as a first obverse surface; the second surface is referred to as a second reverse surface; the first flat portion is referred to as a first obverse surface flat portion; the first projecting portion is referred to as a first obverse surface projecting portion; the second flat portion is referred to as a second reverse surface flat portion; and the second projecting portion is referred to as a second reverse surface projecting portion,

wherein the first member includes the first obverse surface and a first reverse surface facing the second side,

the electronic element includes an element obverse surface facing the first obverse surface in the thickness direction,

the second member includes a second obverse surface facing the first side in the thickness direction and the second reverse surface,

the first obverse surface includes the first obverse surface flat portion and the first obverse surface projecting portion,

the first reverse surface includes a first reverse surface flat portion,

the second obverse surface includes a second obverse surface flat portion, and

the second reverse surface includes the second reverse surface flat portion and the second reverse surface projecting portion.

Clause 3. The electronic device according to clause 2, wherein the first reverse surface is not covered by the sealing resin.

Clause 4. The electronic device according to clause 2 or 3, wherein the second obverse surface includes a second obverse surface recessed portion, and

the second obverse surface recessed portion is sunk toward the second side with respect to the second obverse surface flat portion.

Clause 5. The electronic device according to any of clauses 2 to 4, wherein the first reverse surface includes a first reverse surface recessed portion, and

the first reverse surface recessed portion is sunk toward the first side with respect to the first reverse surface flat portion.

Clause 6. The electronic device according to any of clauses 2 to 5, wherein the first member includes a first side surface extending in the thickness direction, and the first obverse surface projecting portion is in contact with the first side surface.

Clause 7. The electronic device according to any of clauses 2 to 6, wherein the connecting portion includes a second side surface extending in the thickness direction, and the second reverse surface projecting portion is in contact with the second side surface.

Clause 8. The electronic device according to clause 1, wherein the one side is referred to as a second side; the opposite side is referred to as a first side; the first surface is referred to as a first reverse surface; the second surface is referred to as a second obverse surface; the first flat portion is referred to as a first reverse surface flat portion; the first projecting portion is referred to as a first reverse surface projecting portion; the second flat portion is referred to as a second obverse surface flat portion; and the second projecting portion is referred to as a second obverse surface projecting portion,

wherein the first member includes a first obverse surface facing the first side and the second reverse surface,

the electronic element includes an element obverse surface facing the first obverse surface in the thickness direction,

the second member includes the second obverse surface and a second reverse surface facing the second side,

the first reverse surface includes the first reverse surface flat portion and the first reverse surface projecting portion,

the first obverse surface includes a first obverse surface flat portion,

the second reverse surface includes a second reverse surface flat portion,

the second obverse surface includes the second obverse surface flat portion and the second obverse surface projecting portion.

Clause 9. The electronic device according to any of clauses 1 to 8, wherein the connecting member is a wire.

Clause 10. The electronic device according to clause 1, wherein the connecting member is a metal plate.

Clause 11. A method for manufacturing an electronic device, the method comprising:

preparing a first die and a second die, with the first die being disposed on one side in a thickness direction with respect to a metal plate material and with the second die being disposed on an opposite side in the thickness direction with respect to the metal plate material;

moving the first die and the second die past each other in the thickness direction, thereby causing a portion of the metal plate material held in contact with the first die to provide a first member remaining in the metal plate material;

preparing a third die and a fourth die, with the third die being disposed on the opposite side in the thickness direction with respect to the metal plate material and with the fourth die being disposed on the one side in the thickness direction with respect the metal plate material;

moving the third die and the fourth die past each other in the thickness direction, thereby causing a portion of the metal plate material held in contact with the third die to provide a second member remaining in the metal plate material and including a terminal portion and a connecting portion;

mounting an electronic element on the first member;

connecting a connecting member to the electronic element and to the connecting portion; and

forming a sealing resin covering at least a part of the first member, the electronic element, the connecting portion, and the connecting member.

### REFERENCE NUMERALS

A100, A200: Electronic device 1: Electronic element 1A: Electronic element 1B: Electronic element 1a: Element obverse surface 1b: Element reverse surface 2: First member 3: Second member 3A: Second member 3B: Second member 4: Second member 6: Sealing resin 11: Obverse surface electrode 12: Drain electrode 13: Obverse surface electrode 14: Reverse surface electrode 19: Conductive bonding material 20: Semiconductor element 21: First obverse surface 21a: First obverse surface flat portion 21b: First obverse surface projecting portion 21c: First obverse surface recessed portion 22: First reverse surface 22a: First reverse surface flat portion 22b: First reverse surface recessed portion 22c: First reverse surface projecting portion 23: First side surface 25: Pad portion 26: Extending portion 27: Protruding portion 28: Linking portion 29: Terminal portion 31: Second obverse surface 31a: Second obverse surface flat portion 31b: Second obverse surface recessed portion 31c: Second obverse surface projecting portion 32: Second reverse surface 32a: Second reverse surface flat portion 32b: Second reverse surface projecting portion 32c: Second reverse surface recessed portion 33: Second side surface 35: Connecting portion 36: Terminal portion 41: Second obverse surface 41a: Second obverse surface flat portion 41b: Second obverse surface recessed portion 41c: Second obverse surface projecting portion 42: Second reverse surface 42a: Second reverse surface flat portion 42b: Second reverse surface projecting portion 42c: Second reverse surface recessed portion 43: Second side surface 45: Connecting portion 46: Terminal portion 51: Connecting member 52: Connecting member 53: Connecting member 54: Connecting member 61: Resin obverse surface 62: Resin reverse surface 63: Resin side surface 64: Resin side surface 65: Resin side surface 66: Resin side surface 69: Groove 71: Metal plate material 73: First die 74: Second die 75: Third die 76: Fourth die 91: Heat sink 92: Circuit board 101: Semiconductor layer 102: Semiconductor layer 111: Gate electrode 112: Source electrode 261: Root portion 262: Bent portion 263: Front end portion 281: Through-hole 291: First part 292: Second part 293: Third part 361: Root portion 362: Bent portion 363: Front end portion 461: Root portion 462: Bent portion 463: Front end portion 510: Loop portion 511: Bonding portion 512: Bonding portion 520: Loop portion 521: Bonding portion 522: Bonding portion 530: Loop portion 531: Bonding portion 532: Bonding portion 711: Frame portion 919: Sheet material 921: Solder x: First direction x1: First side x2: Second side y: Second direction y1: First side y2: Second side z: Thickness direction z1: First side z2: Second side

1. An electronic device comprising:
a first member including a first surface facing one side in a thickness direction;
an electronic element mounted on the first member;
a connecting member electrically connected to the electronic element;
a second member including a second surface facing an opposite side in the thickness direction, the second member including a terminal portion and a connecting portion to which the connecting member is connected; and
a sealing resin covering a part of the first member, a part of the second member, the electronic element and the connecting member,
wherein the first surface includes a first flat portion and a first projecting portion,
the first projecting portion projects toward the one side with respect to the first flat portion,
the second surface includes a second flat portion and a second projecting portion, and
the second projecting portion projects toward the opposite side with respect to the second flat portion.

2. The electronic device according to claim 1, wherein the one side is referred to as a first side; the opposite side is referred to as a second side; the first surface is referred to as a first obverse surface; the second surface is referred to as a second reverse surface; the first flat portion is referred to as a first obverse surface flat portion; the first projecting portion is referred to as a first obverse surface projecting portion; the second flat portion is referred to as a second reverse surface flat portion; and the second projecting portion is referred to as a second reverse surface projecting portion,
wherein the first member includes the first obverse surface and a first reverse surface facing the second side,
the electronic element includes an element obverse surface facing the first obverse surface in the thickness direction,
the second member includes a second obverse surface facing the first side in the thickness direction and the second reverse surface,
the first obverse surface includes the first obverse surface flat portion and the first obverse surface projecting portion,
the first reverse surface includes a first reverse surface flat portion,
the second obverse surface includes a second obverse surface flat portion, and
the second reverse surface includes the second reverse surface flat portion and the second reverse surface projecting portion.

3. The electronic device according to claim 2, wherein the first reverse surface is not covered by the sealing resin.

4. The electronic device according to claim 2, wherein the second obverse surface includes a second obverse surface recessed portion, and
the second obverse surface recessed portion is sunk toward the second side with respect to the second obverse surface flat portion.

5. The electronic device according to claim 2, wherein the first reverse surface includes a first reverse surface recessed portion, and
the first reverse surface recessed portion is sunk toward the first side with respect to the first reverse surface flat portion.

6. The electronic device according to claim 2, wherein the first member includes a first side surface extending in the thickness direction, and the first obverse surface projecting portion is in contact with the first side surface.

7. The electronic device according to claim 2, wherein the connecting portion includes a second side surface extending in the thickness direction, and the second reverse surface projecting portion is in contact with the second side surface.

8. The electronic device according to claim 1, wherein the one side is referred to as a second side; the opposite side is referred to as a first side; the first surface is referred to as a first reverse surface; the second surface is referred to as a second obverse surface; the first flat portion is referred to as a first reverse surface flat portion; the first projecting portion is referred to as a first reverse surface projecting portion; the second flat portion is referred to as a second obverse surface flat portion; and the second projecting portion is referred to as a second obverse surface projecting portion,
wherein the first member includes a first obverse surface facing the first side and the second reverse surface,
the electronic element includes an element obverse surface facing the first obverse surface in the thickness direction,
the second member includes the second obverse surface and a second reverse surface facing the second side,
the first reverse surface includes the first reverse surface flat portion and the first reverse surface projecting portion,
the first obverse surface includes a first obverse surface flat portion,
the second reverse surface includes a second reverse surface flat portion,
the second obverse surface includes the second obverse surface flat portion and the second obverse surface projecting portion.

9. The electronic device according to claim 1, wherein the connecting member is a wire.

10. The electronic device according to claim 1, wherein the connecting member is a metal plate.

11. A method for manufacturing an electronic device, the method comprising:
preparing a first die and a second die, with the first die being disposed on one side in a thickness direction with respect to a metal plate material and with the second die being disposed on an opposite side in the thickness direction with respect to the metal plate material;
moving the first die and the second die past each other in the thickness direction, thereby causing a portion of the metal plate material held in contact with the first die to provide a first member remaining in the metal plate material;
preparing a third die and a fourth die, with the third die being disposed on the opposite side in the thickness direction with respect to the metal plate material and with the fourth die being disposed on the one side in the thickness direction with respect the metal plate material;
moving the third die and the fourth die past each other in the thickness direction, thereby causing a portion of the metal plate material held in contact with the third die to provide a second member remaining in the metal plate material and including a terminal portion and a connecting portion;
mounting an electronic element on the first member;
connecting a connecting member to the electronic element and to the connecting portion; and
forming a sealing resin covering at least a part of the first member, the electronic element, the connecting portion, and the connecting member.
